(19) United States
(12) Patent Application Publication
(10) Pub. No.: US 2012/0217391 A1
(43) Pub. Date: Aug. 30, 2012

(54) CHARGED PARTICLE MICROSCOPE

(76) Inventors: Hiroyasu Shichi, Tokyo (JP); Shinichi Matsubara, Chofu (JP); Noriaki Arai, Hitachinaka (JP); Tohru Ishitani, Sayama (JP); Yoichi Ose, Mito (JP); Yoshimi Kawanami, Hitachinaka (JP)

(21) Appl. No.: 13/508,040

(22) PCT Filed: Nov. 1, 2010
(86) PCT No.: PCT/JP2010/006425

§ 371 Date: May 3, 2012

(30) Foreign Application Priority Data
Nov. 6, 2009 (JP) 2009-254562

(51) Int. Cl. H01J 37/28

(52) U.S. Cl. 250/306

(57) ABSTRACT

The charged particle beam microscope is configured of: a gas field ionization ion source (1); a focusing lens (5) which accelerates and focuses ions that have been discharged from the ion source; a movable first aperture (6) which limits the ion beam that has passed through the focusing lens; a first deflector (35) which scans or aligns the ion beam that has passed through the first aperture; a second deflector (7) which deflects the ion beam that has passed through the first aperture; a second aperture (36) which limits the ion beam that has passed through the first aperture; an objective lens (8) which focuses, on a sample, the ion beam that has passed through the first aperture; and a means for measuring the signal, which is substantially proportional to the current of the ion beam that has passed through the second aperture.

### TECHNICAL FIELD

The present invention relates to a charged particle microscope.

### BACKGROUND ART

Irradiating a sample with an electron while scanning the electron and detecting secondary charged particles discharged from the sample enables observation of a structure of a sample front surface. This is called a scanning electron microscope (hereinafter abbreviated as SEM). On the other hand, irradiating a sample with an ion beam while scanning the ion beam and detecting secondary charged particles discharged from the sample also enables the observation of the structure of the sample front surface. This is called a scanning ion microscope (hereinafter abbreviated as SIM). Irradiating especially an ion type such as hydrogen or helium having light mass to the sample relatively reduces spatter action which is preferable for the sample observation.

Further, the ion beam is characterized by being more sensitive to information of the sample front surface than the electron beam. This is because an excited region of the secondary charged particles, compared to a case of the electron beam irradiation, is localized by the sample front surface. Moreover, for the electron beam, a property as an electron wave cannot be ignored, and thus aberration occurs by diffraction effect. On the other hand, the ion beam is heavier than the electron, and thus the diffraction effect can be ignored.

Moreover, irradiating the ion beam to the sample and detecting ions transmitted through the sample can provide information on which an inner structure of the sample is reflected. This is called a transmitted ion microscope. Irradiating the ion kind such as the hydrogen or the helium having light mass to the sample results in a larger ratio of transmission through the sample, which is preferable for the observation.

On the contrary, irradiating an ion kind such as oxygen, nitrogen, argon, krypton, xenon, gallium, or indium having heavy mass to the sample is preferable for machining the sample through the spatter action. Especially known as an ion beam machining device is a focused ion beam device (hereinafter FIB) using a liquid metal ion source (hereinafter LMIS). Further, used in recent years has been an FIB-SEM device as a complex machine of the scanning electron microscope (SEM) and the focused ion beam (FIB). With the FIB-SEM device, irradiating the FIB to form a rectangle hole at a desired section enables SEM observation of its cross section. Moreover, the sample machining is also possible by generating a gas ion of, for example, oxygen, nitrogen, argon, krypton, or xenon by a plasma ion source or a gas electric field dissociation ion source and irradiating it to the sample.

However, for the ion microscope mainly intended for the sample observation, the gas electric field dissociation ion source is preferable as an ion source. The gas electric field dissociation ion source supplies gas such as hydrogen or helium to a metal emitter tip whose tip end has a curvature radius of approximately 100 nm and then applies high voltage of several kV or above to the emitter tip to thereby dissociate a gas molecule and extracts this as an ion beam. This ion source is characterized by being capable of generating an ion beam with a narrow energy width and also generating a minute ion beam since an ion generation source is small in size.

With the ion microscope, sample observation with a high signal-noise ratio requires providing on the sample an ion beam with great current density. To this end, it is required to increase ion radiation angle current density of the electric field dissociation ion source. To increase the ion radiation angle current density, molecule density of ion material gas (ionized gas) near the emitter tip can be increased. The gas molecule density per unit pressure is inversely proportional to gas temperature. Thus, the emitter tip may be cooled to extremely low temperature to lower temperature of the gas around the emitter tip. This can increase the molecule density of the ionized gas near the emitter tip. Pressure of the ionized gas around the emitter tip can be set at, for example, approximately 10-2 to 10 Pa.

However, when the pressure of the ion material gas is set at ˜1 pa or above, the ion beam hits neutral gas to be neutralized, reducing ion current. Moreover, an increase in the number of gas molecules in the electric field dissociation ion source increases a frequency of hitting the emitter tip by the gas molecules whose temperature has been increased as a result of hitting a wall of the vacuum container at high temperature. Thus, temperature of the emitter tip increases, reducing the ion current. To this end, provided in the electric field dissociation ion source is a gas ionization chamber mechanically surrounding periphery of the emitter tip. The gas ionization chamber is formed by using an ion extraction electrode provided oppositely to the emitter tip.

Disclosed in Patent Literature 1 is that ion source characteristics improve as a result of forming a minute projected part at a tip end of an emitter tip. Disclosed in Non-Patent Literature 1 is that a minute projected part of an emitter tip is fabricated by using second metal different from a material of the emitter tip. Disclosed in Non Patent Literature 2 is a scanning ion microscope loaded with a gas electric field dissociation ion source which performs helium ion discharge.

Disclosed in Patent Literature 2 is a scanning charged particle microscope including: a gas electric field dissociation ion source including an extraction electrode forming near a tip end of an emitter a gas-ionizing electric field and a cooling means adapted to cool the emitter; a lens system focusing ions extracted from the gas electric field dissociation ion source; a beam deflector scanning an ion beam; a secondary particle detector detecting secondary particles; and an image display means adapted to display a scanning ion microscope image. Also disclosed is that a beam is scanned on a mobile beam restricting diaphragm through deflection action of an upper beam deflector-analyzer, a scanning ion microscope image is created with a signal synchronous to this scanning signal defined as an XY signal and secondary electron detection intensity defined as a Z (luminance) signal, and it is monitor-displayed on an image display means. Further, disclosed is that the scanning ion microscope image on this monitor screen is a corresponding image obtained by folding in and fading an electric field ion microscope image at an ion radiation solid angle corresponding to a diaphragm hole of the mobile beam restricting diaphragm.

Disclosed in Patent Literature 3 is that, in a charged particle microscope loaded with a gas electric field dissociation ion source, obtaining a secondary particle image by detecting with a secondary particle detector secondary particles generated by a mobile shutter arranged below a scanning and deflecting electrode while scanning an ion beam discharged from an emitter tip fitted to a filament mount inside a gas molecule ionization chamber of the gas electric field dissociation ion source enables observation of an ion radiation pattern of the emitter tip and while observing the ion radiation pattern, emitter tip position and angle are adjusted.

Disclosed in Patent Literature 4 is that, in a charged particle radiation device, the device is downsized by providing not an ion pump but a non-evaporated getter as a main exhaust means for an electron source. Moreover, disclosed in Patent Literature 5 is that, in a charged particle radiation device, while measuring electron emission current from a cathode, two micrometers are turned to change position of the cathode and position indicating a maximum value of the emission current is defined as cathode adjustment position, and a method of obtaining a pattern of electron discharge from the cathode by turning the two micrometers while observing an image of electron beam discharged from the cathode via an image of secondary electron discharge in a state in which the electron beam is discharged.

Suggested in Patent Literature 6 is a device that observes and analyzes a defect and a foreign substance by forming a rectangle hole near an abnormal section of a sample by use of an FIB and observing a cross section of this rectangle hole with an SEM device.

Suggested in Patent Literature 7 is a technology of extracting a minute sample for transmission electron microscope observation from a bulk sample by use of an FIB or a probe.

### CITATION LIST

### Patent Literatures

Patent Literature 1: Japanese Patent Application Laid-Open Publication No. S58-85242

Patent Literature 2: Japanese Patent Application Laid-Open Publication No. 2008-140557

Patent Literature 3: Japanese Patent Application Laid-Open Publication No. 2009-163981

Patent Literature 4: Japanese Patent Application Laid-Open Publication No. 2007-311117

Patent Literature 5: Japanese Patent Application Laid-Open Publication No. H8-236052

Patent Literature 6: International Patent Application WO 99/05506

### Non Patent Literatures

Non Patent Literature 1: H.-S. Kuo, I.-S. Hwang, T.-Y. FU, J.-Y. Wu, C.-C. Chang, and T. T. Tsong, Nano Letters 4 (2004) 2379

Non Patent Literature 2: J. Morgan, J. Notte, R. Hill, and B. Ward, Microscopy Today, July 14 (2006) 24

### SUMMARY OF INVENTION

### Technical Problem

A gas electric field dissociation ion source having a nano-pyramid structure at a tip end of a metal emitter faces the following problem. A characteristic of this ion source is use of ions discharged from vicinity of one atom at the tip end of the nano-pyramid. That is, a region where the ions are discharged is narrow and an ion light source is as small as nano meters or below. Thus, focusing a sample at the same magnification ratio as that of the ion light source or increasing a reduction ratio to approximately ½ maximizes the characteristic of the ion source. For a conventional gallium liquid metal ion source, a dimension of an ion light source is assumed to be approximately 50 nm. Therefore, realizing a beam diameter of 5 nm on the sample requires setting the reduction ratio at 1/10 or below. In this case, vibration of the emitter tip of the ion source is reduced to 1/10 or below on the sample. For example, even when the emitter tip is vibrating by 10 nm, vibration of a beam spot on the sample is 1 nm or below. Therefore, an influence of the vibration of the emitter tip on a beam diameter of 5 nm becomes insignificant. However, in this example, the reduction ratio is as small as approximately 1 to ½. Therefore, the vibration of 10 nm at the emitter tip is a vibration of 5 nm on the sample when the reduction ratio is ½, and vibration of the sample with respect to the beam diameter is large. That is, for example, realizing a resolution of 0.2 nm requires setting the vibration of the emitter tip at 0.1 nm or below at a maximum. The conventional ion source is not necessarily satisfactory in a view point of preventing vibration at the tip end of the emitter tip.

Moreover, the inventor of this application found a problem of an increased amplitude of the emitter tip vibration, that is, image resolution caused by upsizing the gas electric field dissociation ion source as a result of upsizing of a mechanical tilt adjustment means of the emitter tip. Moreover, the inventor of this application found that achieving an object of making an ion irradiation system compact, shortening an ion optical length, and realizing a mechanism of accurately adjusting a direction of ion discharge from the emitter tip to a direction towards a sample leads to realization of a charged particle radiation device making use of performance of this ion source.

Moreover, similarly in a view point of axis adjustment of the ion irradiation system, adjustment of axis alignment between the emitter tip and an opening part of the extraction electrode is also an object for realizing an ultrafine beam by reducing aberration upon ion beam thinning.

Moreover, the emitter tip is subjected to high-temperature treatment for control of its tip end. It was found that temperature control at this point can be made by, for example, voltage, current, and resistance, but it is difficult to perform the temperature control with high accuracy at time of cooling to the extremely low temperature. It was found that realizing this temperature control in the high-temperature treatment with high accuracy leads to an improvement in reliability of the gas electric field dissociation ion source.

It is an object of the present invention to provide a charged particle microscope that permits sample observation with high resolution by reducing amplitude of relative vibration between an emitter tip and the sample.

### Solution to Problem

The present invention refers to a charged particle microscope including: a vacuum container; an emitter tip arranged in the vacuum container; an extraction electrode having an opening part through which ions generated by the emitter tip pass; an ion source having the emitter tip and the extraction electrode; a focusing lens focusing an ion beam discharged from the ion source; and a first deflector deflecting the ion beam that has passed through the focusing lens, wherein a first aperture restricting the ion beam that has passed through the focusing lens is provided between the focusing lens and the first deflector.

With this configuration, providing the first aperture between the focusing lens and the first deflector can shorten a space therebetween. This is because heightwise distance can be more reduced, compared to a case where the first deflector is placed between the condensing lens and the first aperture. Moreover, the first deflector here is a deflector which scans the ion beam for the purpose of providing a pattern of ion radiation from the emitter tip. Moreover, the first means a deflector located in a first place from the ion source towards the sample. However, providing a charged particle radiation device which includes, between a first deflector and a focusing lens, a deflector whose length is shorter than length of the first deflector in an optical axis direction and which uses this for adjusting a deflection axis of an ion beam does not depart from the scope of the invention.

Providing the charged particle microscope in which the first aperture is mobile in a direction within a substantially perpendicular plane can restrict the ion beam that has passed through the focusing lens. This can achieve alignment between an opening part of the first aperture and an ion beam optical axis and provides effect that an extremely minute beam with little ion beam distortion is obtained. Further, by varying a size of the opening part of the aperture, or preparing opening parts of different sizes, for example, a plurality of holes of different diameters and selecting the size of the opening part, or selecting the hole of the given diameter and having the ion beam passing therethrough, an angle of opening of the ion beam with respect to the lens is selected. This permits control of a degree of lens aberration, thus providing effect that the ion beam diameter and ion beam current can be controlled.

Further, the invention refers to the charged particle microscope further including: a second deflector deflecting the ion beam that has passed through the first aperture; a second aperture restricting the ion beam that has passed through the first aperture; an objective lens focusing onto a sample the ion beam that has passed through the first aperture; and a signal volume measurement means adapted to measure a signal volume substantially proportional to ion beam current of the ion beam that has passed through the second aperture. As a result, the pattern of the ion radiation from the emitter tip can be provided, enabling emitter tilt angle adjustment and alignment with the ion beam optical axis. Moreover, an ion beam optical system can be shortened, thus resulting in smaller amplitude of relative vibration between the emitter and the sample, which consequently enables high-resolution sample observation.

Further, providing the charged particle microscope in which the second aperture restricts the ion beam that has passed through the objective lens makes it easy to take the pattern of the ion bean radiation and thus increase resolution.

Further, providing the charged particle microscope in which wherein the signal volume measurement means is a charged particle detector detecting secondary particles discharged from the sample as a result of irradiation of the ion beam enables signal volume detection. In particular, a signal-noise ratio can be increased to observe the pattern of the ion radiation from the emitter tip.

Providing the charged particle microscope in which a sample for ion beam adjustment is loaded enables observation of especially the pattern of the ion radiation from the emitter tip in an even state. This also provides effect that a sample to be observed is not contaminated and broken.

Providing the charged particle microscope in which the signal volume measurement means includes at least one of: an ammeter measuring the ion beam current; an ammeter connected to the sample; a means adapted to amplify the ion beam current with a channel thoron for measurement; and a means adapted to achieve amplification with a multi-channel plate for measurement enables the signal volume measurement. Especially the signal-noise ratio can be increased to observe the pattern of the ion radiation from the emitter tip.

Further, providing the charged particle microscope in which the second aperture also serves as an electrode forming the objective lens enables component sharing.

Further, providing the charged particle microscope in which a tip end of the emitter tip is a nano-pyramid can provide a thin beam, enabling sample observation with high resolution.

Further, providing the charged particle microscope including a display means adapted to display an ion radiation pattern of the nano-pyramid permits the emitter tilt angle adjustment and the alignment with the ion beam optical axis with reference to a displayed ion radiation pattern image.

Moreover, providing a charged particle microscope which includes: a vacuum container; an emitter tip arranged in the vacuum container; an extraction electrode having an opening part through which ions generated by the emitter tip pass; an ion source having the emitter tip and the extraction electrode; and a focusing lens focusing an ion beam discharged from the ion source, and which further includes: a tilt angle adjustment means adapted to be capable of adjusting a tilt angle with respect to an irradiation axis of the ion beam; and a display means adapted to display an ion radiation pattern depending on a difference in the tilt angle enables the emitter tilt angle adjustment while viewing an ion radiation pattern. Further, providing the charged particle microscope in which a driving mechanism forming the tilt angle adjustment means is arranged in the ion source, and tilting can be done while position of a tip end of an ion emitter having the emitter tip is kept substantially constant can achieve compactification.

Further, providing the charged particle microscope in which the driving mechanism driving the tilt angle adjustment means uses a piezo element can achieve compactificaiton.

Moreover, providing a charged particle microscope which includes: a vacuum container; an emitter tip arranged in the vacuum container; an extraction electrode having an opening part through which ions generated by the emitter pass; an ion source having the emitter and the extraction electrode; a focusing lens focusing an ion beam discharged from the ion source; and a first deflector deflecting the ion beam that has passed through the focusing lens, and which further includes a light detection means adapted to detect from the opening part light generated from the emitter or a filament connected to the emitter enables observation of the emitter or the filament connected to the emitter.

Further, providing the charged particle microscope further including a change means adapted to change relative position between the emitter and the extraction electrode enables emitter adjustment.

Further, providing a charged particle microscope further including a control means adapted to control, based on a signal detected by the light detection means, at least one of voltage applied to the filament, current, resistance, and temperature enables adjustment of temperature of the filament, which can therefore improve reliability of fabrication or reproduction of a nano-pyramid structure of the emitter and can provide an appropriate ion beam.

Further, providing the charged particle microscope further including a means adapted to permit the light detection means to observe the emitter or the filament connected to the emitter outside of the vacuum container through the opening part enables observation of the emitter or the filament connected to the emitter.

Further, providing the charged particle microscope in which a sample stage loaded with the sample has a mobile function within a plane substantially perpendicular to the ion beam, and the sample stage is provided with a means adapted to permit observation of the emitter or the filament connected to the emitter outside of the vacuum container through the opening part enables the observation of the emitter or the filament connected to the emitter.

Further, providing the charged particle microscope further including a means adapted to permit observation of the emitter or the filament connected to the emitter outside of the vacuum container through the opening part is provided between the focusing lens and the objective lens enables the observation of the emitter or the filament connected to the emitter.

Further, providing the charged particle microscope in which a first aperture is provided between the focusing lens and the first deflector, and at least part of the light detection means is included in the first aperture enables the observation of the emitter or the filament connected to the emitter.

### Advantageous Effects of Invention

The present invention permits high-resolution sample observation in a charged particle radiation device observing a sample by irradiating the sample with charged particles.

### BRIEF DESCRIPTION OF DRAWINGS

FIG. 1 is a schematic configuration diagram of one example of a charged particle radiation device according to the present invention.

FIG. 2 is a schematic configuration diagram of a control system of one example of the charged particle radiation device according to the invention.

FIG. 3 is a schematic configuration diagram of the charged particle radiation device according to the invention.

FIG. 4 is a schematic structure diagram of a cooling mechanism of a gas electric field dissociation ion source of one example of the charged particle radiation device according to the invention.

FIG. 5 is a schematic configuration diagram of the gas electric field dissociation ion source of one example of the charged particle radiation device according to the invention.

FIG. 6A is a schematic configuration diagram of a tilt mechanism in the gas electric field dissociation ion source of one example of the charged particle radiation device according to the invention (before tilt adjustment).

FIG. 6B is a schematic configuration diagram of the tilt mechanism in the gas electric field dissociation ion source of one example of the charged particle radiation device according to the invention (after the tilt adjustment).

FIG. 7A is a schematic configuration diagram of the tilt mechanism in the gas electric field dissociation ion source of one example of the charged particle radiation device according to the invention (before the tilt adjustment).

FIG. 7B is a schematic configuration diagram of the tilt mechanism in the gas electric field dissociation ion source of one example of the charged particle radiation device according to the invention (after the tilt adjustment).

FIG. 8A shows one example of an ion radiation pattern of which image is displayed on a calculation processor of the charged particle radiation device according to the invention (with one atom).

FIG. 8B shows one example of the ion radiation pattern of which image is displayed on the calculation processor of the charged particle radiation device according to the invention (with six atoms).

FIG. 9 is a schematic configuration diagram of one example of the charged particle radiation device according to the invention.

FIG. 10 is a schematic configuration diagram of the control system of one example of the charged particle radiation device according to the invention.

FIG. 11 is a schematic configuration diagram of the control system of one example of the charged particle radiation device according to the invention.

FIG. 12A is a schematic configuration diagram of periphery of a gas molecule ionization chamber in the gas electric field dissociation ion source of one example of the charged particle radiation device according to the invention (with a cover member in an open state).

FIG. 12B is a schematic configuration diagram of the periphery of the gas molecule ionization chamber in the gas electric field dissociation ion source of one example of the charged particle radiation device according to the invention (with the cover member in a closed state).

FIG. 13 shows one example of emitter tip and filament images displayed on the calculation processor of the charged particle radiation device according to the invention.

### DESCRIPTION OF EMBODIMENTS

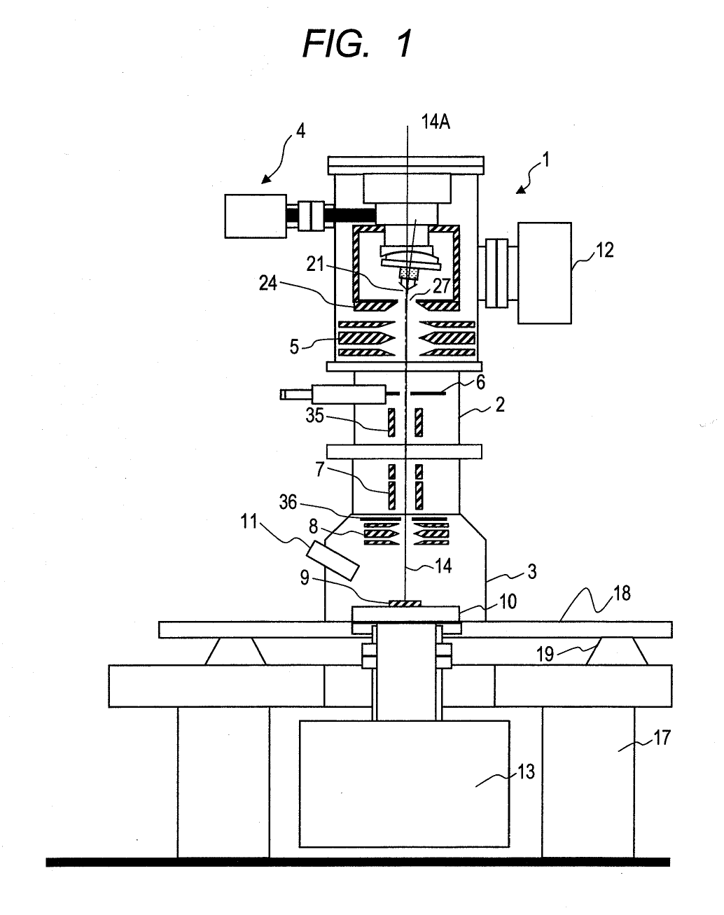

Referring to FIG. 1, an example of a charged particle radiation device according to the present invention will be described. Hereinafter, as an ion beam device, a first example of a scanning ion microscopic device will be described. The scanning ion microscope in this example has: a gas electric field dissociation ion source 1, an ion beam irradiation system column 2, a sample chamber 3, and a cooling mechanism 4. Inside of the gas electric field dissociation ion source 1, the ion beam irradiation system column 2, and the sample chamber 3 here serves as a vacuum container.

Configuration of the gas electric field dissociation ion source will be described in detail below. Included therein are an emitter tip 21 of a need-like shape and an extraction electrode 24 which is provided oppositely to the emitter tip and which has an opening part 27 through which ions pass. Moreover, the ion beam irradiation system is composed of: a focusing lens 5 focusing the ions discharged from the gas electric field dissociation ion source 1 described above; a mobile first aperture 6 restricting an ion beam 14 that has passed through the focusing lens; a first deflector 35 scanning or aligning an ion beam that has passed through the first aperture; a second deflector 7 deflecting the ion beam that has passed through the first aperture; a second aperture 36 restricting the ion beam 14 that has passed through the first aperture; and an objective lens 8 focusing onto a sample the ion beam that has passed through the first aperture.

The first deflector here, to be described in detail below, is a deflector scanning the ion beam for the purpose of providing a pattern of ion radiation from the emitter tip. Moreover, “first” means a deflector located in a first place when viewed from the ion source towards the sample. Note that, however, providing a charged particle radiation device which includes between a first deflector and a focusing lens a deflector having shorter length than that of the first deflector along an optical axis and which uses this for ion beam deflection axis adjustment does not depart from the scope of the invention.

Moreover, provided in the sample chamber 3 are: a sample stage 10 on which a sample 9 is loaded; and a secondary particle detector 11. The ion beam 14 from the gas electric field dissociation ion source 1 is irradiated to the sample 9 via the ion beam irradiation system. Secondary particles from the sample 9 are detected by the secondary particle detector 11. Here, a signal volume measured by the secondary particle detector 11 is substantially proportional to ion beam current that has passed through the second aperture 36.

Also provided are: although not shown, an electronic gun for counteracting charge-up of the sample upon the ion beam irradiation; and a gas gum, near the sample, for supplying etching and deposition gas.

The ion microscope of this example further has: an ion source evacuating pump 12 evacuating the gas electric field dissociation ion source 1; and a sample chamber evacuating pump 13 evacuating the sample chamber 3. Arranged on a device mount 17 arranged on a floor 20 is a base plate 18 with a vibration absorption mechanism 19 in between. The gas electric field dissociation ion source 1, the ion beam irradiation system column 2, and the sample chamber 3 are supported by the base plate 18. The cooling mechanism 4 cools inside of the gas electric field dissociation ion source 1, the emitter tip 21, the extraction electrode 24, etc. For example, when a Gifford-McMahon type (GM-type) freezer is used as the cooling mechanism 4, installed on the floor 20 is a compressor unit (compressor), not shown, which uses helium gas as working gas. Vibration of the compressor unit (compressor) is transmitted to the device mount 17 via the floor 20. Arranged between the device mount 17 and the base plate 18 is the vibration absorption mechanism 19 which is characterized in that high-frequency vibration of the floor is hardly transmitted to the gas electric field dissociation ion source 1, the ion beam irradiation system column 2, the sample chamber 3, etc. This therefore provides a characteristic such that vibration of the compressor unit (compressor) is hardly transmitted to the gas electric field dissociation ion source 1, the ion beam irradiation system column 2, the sample chamber 3, etc. via the floor 20. Described here as a cause of the vibration of the floor 20 are a freezer 40 and a compressor 16. However, the cause of the vibration of the floor 20 is not limited to them.

Moreover, the vibration absorption mechanism 19 may be formed of vibration absorbing rubber, a spring, or a dumper, or all of them in combination.

In this example, the vibration absorption mechanism 19 is provided on the device mount 17, but the vibration absorption mechanism 19 may be provided at legs of the device mount 17 or they may be combined together.

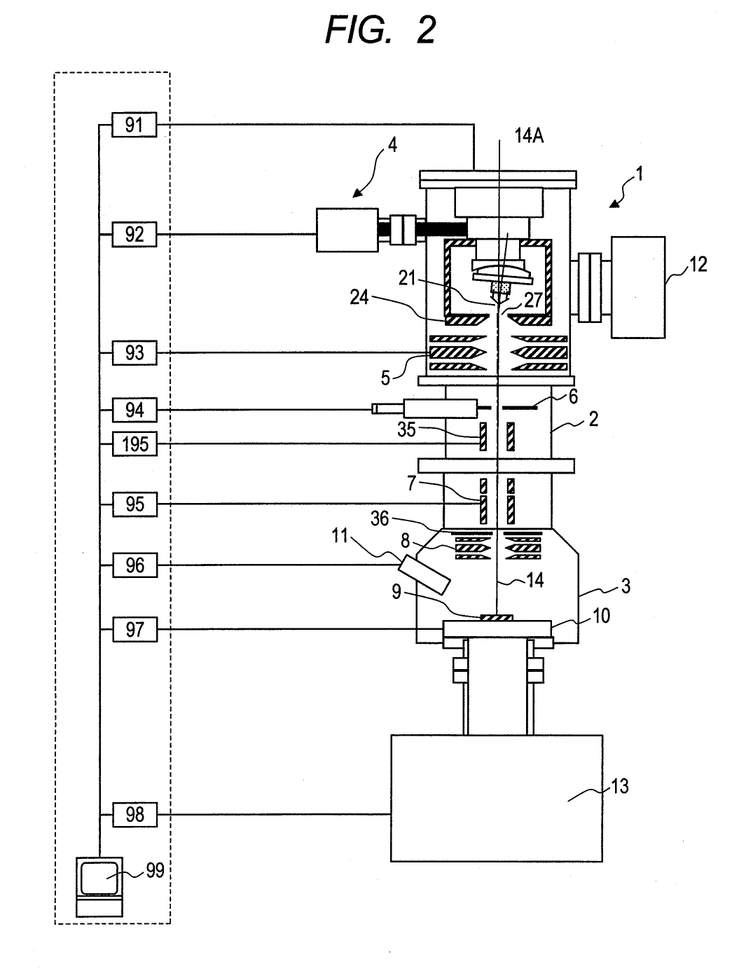

FIG. 2 shows an example of controllers of the ion microscope according to the present invention shown in FIG. 1. The controllers include: an electric field dissociation ion source controller 91 which controls the gas electric field dissociation ion source 1; a freezer controller 92 which controls the freezer 40; a lens controller 93 which controls the focusing lens 5 and the objective lens; a first aperture controller 94 which controls the mobile first aperture 6; a first deflector controller 195 which controls the first deflector; a second deflector controller 95 which controls the second deflector; a secondary electron detector controller 96 which controls the secondary particle detector 11; a sample stage controller 97 which controls the sample stage 10; an evacuating pump controller 98 which controls the sample chamber evacuating pump 13; and a calculation processor 99 which includes an arithmetic unit. The calculation processor 99 includes an image display part. The image display part displays an image generated from a detection signal of the secondary particle detector 11 and information inputted by an input means.

The sample stage 10 has: a mechanism of linearly moving the sample 9 within a sample loading plane in two orthogonal directions; a mechanism of linearly moving the sample 9 in a direction perpendicular to the sample loading plane; and a mechanism of rotating the sample 9 within the sample loading plane. The sample stage 10 further includes a tilt function capable of rotating the sample 9 around a tilt axis to thereby change an angle of irradiation of the ion beam 14 to the sample 9. These controls are executed by the sample stage controller 97 based on commands from the calculation processor 99.

Operation of the ion beam irradiation system of the ion microscope of this example will be described. The operation of the ion beam irradiation system is controlled by commands from the calculation processor 99. The ion beam 14 generated by the gas electric field dissociation ion source 1 is focused by the focusing lens 5, has its beam diameter restricted by the beam restricting aperture 6, and is focused by the objective lens 8. The focused beam is irradiated onto the sample 9 on the sample stage 10 while scanned thereon.

The secondary particles discharged from the sample are detected by the secondary particle detector 11. The signal from the secondary particle detector 11 is subjected to luminance modulation and is transmitted to the calculation processor 99. The calculation processor 99 generates a scanning ion microscope image and displays it at the image display part. This can realize high-resolution observation of a sample front surface.

The first aperture is mobile in a direction within a plane substantially perpendicular to an ion beam irradiation axis 14a, and can bring an opening part of the first aperture in alignment with an ion beam optical axis, providing effect that an extremely fine beam with little ion beam distortion can be obtained. Further, by varying a size of the opening part of the aperture, or preparing opening parts of different sizes, for example, a plurality of holes of different diameters and selecting the size of the opening part, or selecting the hole of the given diameter and having the ion beam passing therethrough, an angle of opening of the ion beam with respect to the lens is selected. This permits control of a degree of lens aberration, thus providing effect that the ion beam diameter and the ion beam current can be controlled.

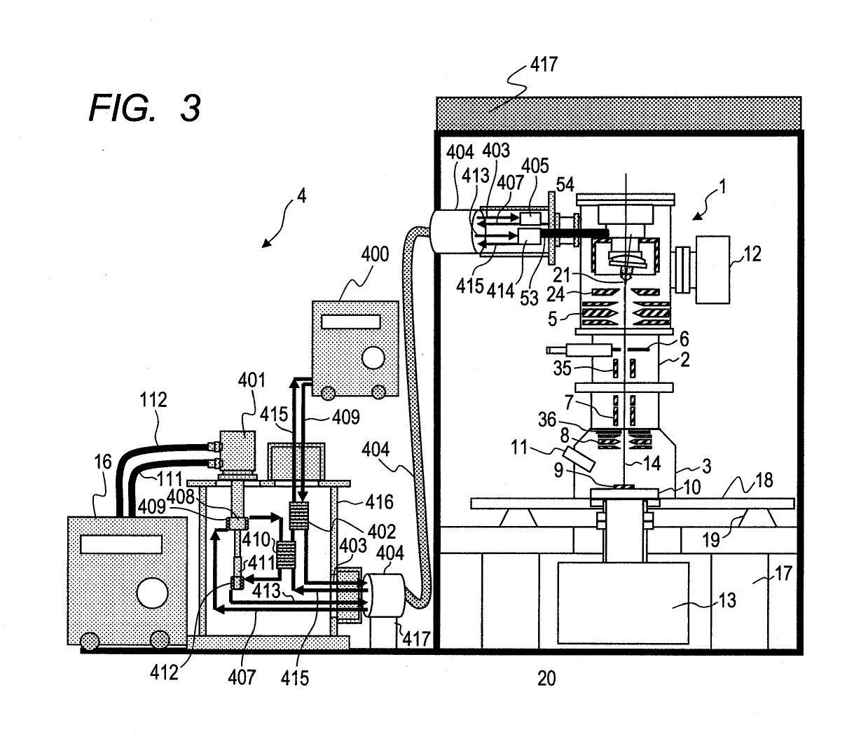

Next, referring to FIG. 3, one example of the charged particle radiation device according to the invention will be described. In this figure, one example of the cooling mechanism 4 of the charged particle radiation device shown in FIG. 1 will be described in detail. The cooling mechanism 4 of this example adopts a helium circulation system. The cooling mechanism 4 of this example cools helium gas as a refrigerant by use of a GM type freezer 401 and heat exchangers 402, 406, 407, and 408 and circulates this by a compressor unit 400. The helium gas which is pressurized by a compressor 403 and which has, for example, 0.9 Mpa and a normal temperature of 300K flows into the heat exchanger 402 through a pipe 409, and is heat-exchanged with returning, low-temperature helium gas (to be described below) to be cooled to a temperature of approximately 60K. The cooled helium gas is transported through a pipe 403 in an insulated transfer tube 404 and flows into a heat exchanger 405 arranged near the gas electric field dissociation ion source 1. Here, the thermal conductor 406 thermally integrated with the heat exchanger 405 is cooled to a temperature of approximately 65K to cool the aforementioned radiation shield, etc. The warmed helium gas flows out of the heat exchanger 405, flows through a pipe 407 to a heat exchanger 409 thermally integrated with a first cooling stage 408 of the GM-type freezer 401, is cooled to a temperature of approximately 50K, and flows to a heat exchanger 410. It is heat-exchanged with the returning, low-temperature helium gas (to be described below) to be cooled to a temperature of approximately 15K, then flows to a heat exchanger 412 thermally integrated with a second cooling stage 411 of the GM type freezer 401, is cooled to a temperature of approximately 9K, is transported through a pipe 413 in the transfer tube 404, flows to a heat exchanger 414 arranged near the gas electric field dissociation ion source 1, and cools a cooling conducting bar 53 as a favorable heat conductor thermally connected to the heat exchanger 414. The helium gas warmed by the heat exchanger 414 sequentially flows to the heat exchangers 410 and 402 through a pipe 415, is heat-exchanged with the helium gas described above to turn to a substantially normal temperature of approximately 275K, and is collected by the compressor unit 400 through the pipe 415. The low-temperature part described above is stored in a vacuum insulation container 416, and is intermittently connected with the transfer tube 404, although not shown. Moreover, in the vacuum insulation container 416, the low temperature part (although not shown) prevents heat penetration due to heat radiated from a room temperature part by, for example, a radiation shield plate or a laminate insulation material.

Moreover, the transfer tube 404 is firmly fixed and supported by the floor 20 or a support body 417 set on the floor 20. Here, the pipes 403, 407, 413, and 415 fixed and supported inside of the transfer tube 404 by a plastic insulation body with glass fibers as an insulation material with low heat conductivity (not shown) are also fixed and supported by the floor 20. Moreover, near the gas electric field dissociation ion source 1, the transfer tube 404 is supported and fixed by the base plate 18, and the pipes 403, 407, 413, and 415 fixed and supported inside the transfer tube 404 by the plastic insulation body with glass fibers as the insulation material with low heat conductivity (not shown) are also fixed and supported by the base plate 18.

Specifically, the cooling mechanism is a cooling mechanism of cooling a cooled body by: a coolness generating means adapted to generate coolness by expanding first high-pressure gas generated by the compressor unit 16; and helium gas as a second moving refrigerant which is cooled by the coolness of this coldness generating means and which is circulated by the compressor unit 400.

The cooling conducting bar 53 is connected to the emitter tip 21 via a copper graticule 54 of a deformable type and a sapphire base. This realizes cooling of the emitter tip 21. In this example, the GM-type freezer causes floor vibration, but the gas electric field dissociation ion source 1, the ion beam irradiation system column 2, the sample chamber 3, etc. are set separately from the GM-type freezer, and further the pipes 403, 407, 413, and 415 coupled to the heat exchangers 405 and 414 set near the gas electric field dissociation ion source 1 are firmly fixed and supported by the hardly vibrating floor 20 and base plate 18 and thereby do not vibrate, and are further insulated from vibration from the floor, and therefore this example is characterized by serving as a system that hardly transmits mechanical vibration.

As described above, with the electric field dissociation ion source and the charged particle radiation device according to the invention, the vibration from the cooling mechanism is hardly transmitted to the emitter tip, and an emitter base mount fixing mechanism is included, preventing vibration of the emitter tip and making it possible to perform high-resolution observation.

Further, the inventor of this application found that sound of the compressor 16 or 400 vibrates the gas electric field dissociation ion source 1 to degrade its resolution. Thus, in this example, a cover 417 spatially separating the compressor and the gas electric field dissociation ion source from each other is provided. This can reduce an influence of the vibration attributable to the sound of the compressor. This enables high-resolution observation.

Moreover, in case of this example, second helium gas is circulated by use of the compressor 400, but the same effect can be provided by communicating pipes 111 and 112 of the helium compressor 16 with the pipes 409 and 416 respectively via flow control valves (not shown), supplying part of the helium gas of the helium compressor 16, that is, the circulating helium gas, as second helium gas into the pipe 409, and collecting the gas with the pipe 416 to the helium compressor 16.

Moreover, in this example, the GM-type freezer 40 is used but a pulse tube freezer or a Sterling type freezer may be used instead. Moreover, in this example, the freezer has two cooling stages but may have a single cooling stage, and thus the number of cooling stages is not specifically limited. For example, using a compact Sterling type freezer with one cooling stage to provide a helium circulating freezer having a minimum cooling temperature of 50K can realize a compact, low-cost ion beam device. Moreover, in this case, neon gas or hydrogen may be used instead of helium gas.

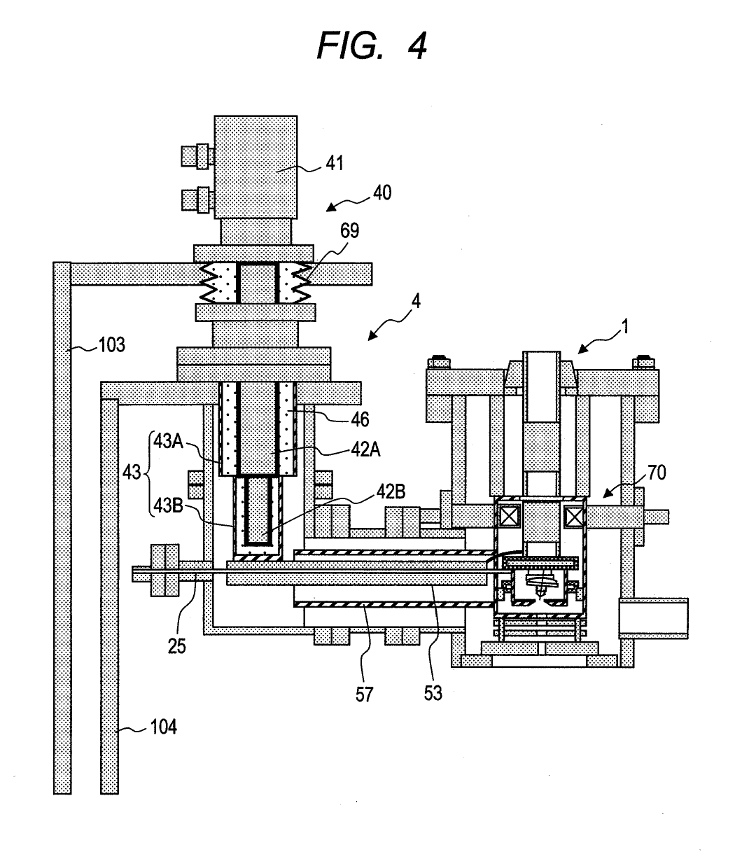

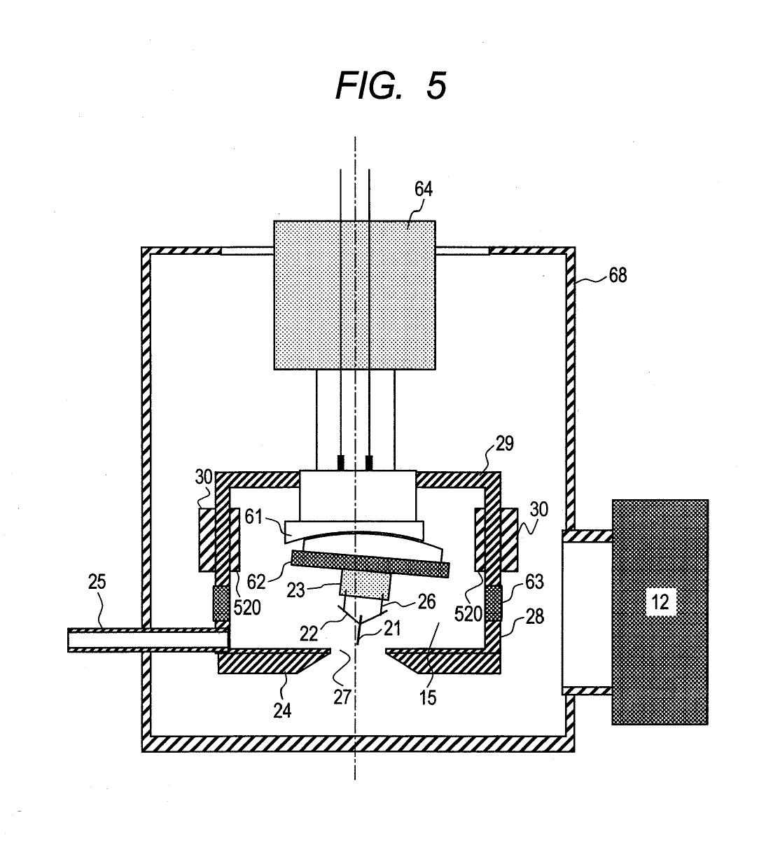

FIG. 4 shows one example of the gas electric field dissociation ion source 1 and its cooling mechanism 4 of the charged particle radiation device according to the invention shown in FIG. 1. The gas electric field dissociation ion source 1 will be described in detail in FIG. 5. Here, the cooling mechanism 4 will be described. In this example, as the cooling mechanism 4 of the gas electric field dissociation ion source 1, a cooling mechanism combining together the GM-type freezer 40 and a helium gas pot 43 is used. A central axis line of the GM-type freezer is arranged in parallel to an optical axis of the ion beam irradiation system passing through the emitter tip 21 of the ion microscope. This can achieve both an improvement in ion beam focusing performance and an improvement in a cooling function.

The GM-type freezer 40 has a main body 41, a first cooling stage 42A, and a second cooling stage 42B. The main body 41 is supported by a support post 103. The first cooling stage 42A and the second cooling stage 42B are structured to be suspended by the main body 41.

An outer diameter of the first cooling stage 42A is larger than an outer diameter of the second cooling stage 42B. Cooling capability of the first cooling stage 42A is approximately 5 W, and cooling capability of the second cooling stage 42B is approximately 0.2 W. The first cooling stage 42A is cooled to approximately 50K. The second cooling stage 42B can be cooled to 4K.

An upper end part of the first cooling stage 42A is surrounded by a bellows 69. A lower end part of the first cooling stage 42A and the second cooling stage 42B are covered by the gas-sealing pot 43. The pot 43 has a portion 43A with a large diameter so formed as to surround the first cooling stage 42A and a portion 43B with a small diameter so formed as to surround the second cooling stage 42B. The pot 43 is supported by a support post 104. The support post 104 is supported by the base plate 18 as shown in FIG. 1.

The bellows 69 and the pot 43 have a sealing structure inside of which helium gas 46 is filled as a heat conducting medium. The two cooling stages 42A and 42B are surrounded by the helium gas 46 but do not make contact with the pot 43. Note that neon gas or hydrogen may be used instead of the helium gas.

In the GM-type freezer 40 of this example, the first cooling stage 42A is cooled to approximately 50K. Thus, the helium gas 46 around the first cooling stage 42A is cooled to approximately 70K. The second cooling stage 42B is cooled to 4K. The helium gas 46 around the second cooling stage 42B is cooled to approximately 6K. In this manner, a lower end of the pot 43 is cooled to approximately 6K.

Vibration of the main body 41 of the GM-type freezer 40 is transmitted to the support post 103 and the two cooling stages 42A and 42B. The vibration transmitted to the cooling stages 42A and 42B attenuates by the helium gas 46. Even when the cooling stages 42A and 42B of the GM-type freezer vibrate, the helium gas is present in the middle, and thus heat is conducted but the mechanical vibration attenuates and the vibration is hardly transmitted to the sealing-type pot 43 cooled by the first cooling stage 41 and the second cooling stage 42. Especially vibration with high vibration frequency is hardly transmitted. That is, provided is effect that mechanical vibration of the pot 43 decreases extremely more than the mechanical vibration of the first cooling stages 42A and 42B of the GM-type freezer. As described with reference to FIG. 1, vibration of the compressor 16 is transmitted to the device mount 17 via the floor 20, and the vibration absorption mechanism 19 prevents this vibration from being transmitted to the base plate 18. Therefore, the vibration of the compressor 16 is not transmitted to the support post 104 and the pot 43.

A lower end of the pot 43 is connected to the cooling conducting bar 53 of copper with high heat conductivity. A gas supply pipe 25 is provided in the cooling conducting bar 53. The cooling conducting bar 53 is covered by a cooling conducting tube 57 of copper.

In this example, connected to the portion 43A of the large diameter of the pot 43 is the radiation shield (not shown), which is connected to the cooling conducting tube 57 of copper. Therefore, the cooling conducting bar 53 and the cooling conducting tube 57 are always held at the same temperature as that of the pot 43.

In this example, the GM-type freezer 40 is used, but a pulse tube freezer or a Sterling type freezer may be used instead. Moreover, in this example, the freezer has the two cooling stages, but may have a single cooling stage and the number of cooling stages is not specifically limited.

Referring to FIG. 5, configuration of the gas electric field dissociation ion source 1 of the charged particle radiation device according to the invention will be described in more detail. The gas electric field dissociation ion source of this example has: the emitter tip 21, a pair of filaments 22, a filament mount 23, a support bar 26, and an emitter base mount 64. The emitter tip 21 is connected to the filaments 22. The filaments 22 are fixed to the support bar 26. The support bar 26 is supported by the filament mount 23. The filament mount 23 is fixed to a tilt mechanism 61 using a piezo element and the emitter base mount 64 with an insulation material 62 in between. The emitter base mount 64 is fitted to a top flange 51 as shown in FIG. 4. The tilt mechanism 61 using the piezo element will be described in detail below.

The gas electric field dissociation ion source of this example further has: an extraction electrode 24, a resistive heater 30 of a cylindrical shape, side walls 28 of a cylindrical shape, and a top panel 29. The extraction electrode 24 is arranged oppositely to the emitter tip 21, and has an opening part 27 for passage of the ion beam 14 therethrough. In the side wall 28, an insulation material 63 is inserted, which permits application of high voltage to the extraction electrode.

The side walls 28 and the top panel 29 surround the emitter tip 21. Space surrounded by the extraction electrode 24, the side walls 28, the top panel 29, the insulation materials 63, and the filament mount 23 is called a gas molecule ionization chamber 15. The gas molecule ionization chamber is a room for increasing gas pressure around the emitter tip, and is not limited to elements forming its wall.

Moreover, to the gas molecule ionization chamber 15, the gas supply pipe 25 is connected. By this gas supply pipe 25, ion material gas (ionized gas) is supplied to the emitter tip 21. The ion material gas (ionized gas) is helium or hydrogen.

The gas molecule ionization chamber 15 excluding the hole 27 of the extraction electrode 24 and the gas supply pipe 25 is sealed. Gas supplied into the gas molecule ionization chamber via the gas supply pipe 25 never leaks from a region other than the hole 27 of the extraction electrode and the gas supply pipe 25. Providing a satisfactorily small area of the opening part 27 of the extraction electrode 24 can hold high air-tightness and sealing performance inside the gas molecule ionization chamber. Where the opening part of the extraction electrode 24 is, for example, the circular hole 27, its diameter is, for example, 0.3 mm. Consequently, as a result of supplying the ionized gas from the gas supply pipe 25 to the gas molecule ionization chamber 15, gas pressure of the gas molecule ionization chamber 15 becomes larger than gas pressure of the vacuum container by at least one digit. This can reduce a ratio in which the ion beam hits the gas in vacuum to be neutralized, generating an ion beam of great current.

The resistive heater 30 is used for degassing the extraction electrode 24, the side walls 28, etc. The degassing is performed by heating the extraction electrode 24, the side walls 28, etc. The resistive heater 30 is arranged outside of the gas molecule ionization chamber 15. Therefore, even when the resistive heater itself is degassed, it is performed outside of the gas molecule ionization chamber, which can highly vacuumize inside of the gas molecule ionization chamber.

In this example, the resistive heater is used for the degassing, but a heating lamp may be used instead. The heating lamp can heat the extraction electrode 24 without making contact with it, which can therefore simplify a structure around the extraction electrode. Further, the heating lamp does not require application of high voltage, which therefore simplifies a structure of a heating lamp power source. Further, instead of using the hot resistive heater, inactive gas may be supplied via the gas supply pipe 25 to heat the extraction electrode, the side walls, etc. for the degassing. In this case, the gas heating mechanism can be turned to grounding potential. Further, a surrounding structure of the extraction electrode is simplified and also wiring and a power source are not required.

By a resistive heater fitted to the sample chamber 3 and the sample chamber evacuating pump 13, the sample chamber 3 and the sample chamber evacuating pump 13 may be heated to approximately 200 degrees Celsius so that a degree of vacuum of the sample chamber 3 becomes equal to or smaller than 10-7 Pa or below at a maximum. This avoids adhesion of contamination to a front surface of the sample upon ion beam irradiation to the sample, enabling favorable observation of the sample front surface. With the conventional technology, upon irradiation of a helium or hydrogen ion beam to the sample front surface, deposition growth by the contamination is fast, which therefore makes it difficult to observe the sample front surface in some cases. Thus, the sample chamber 3 and the sample chamber evacuating pump 13 are subjected to heating treatment in a vacuum state to reduce remaining hydrocarbon-based gas in the vacuum of the sample chamber 3 to a small amount. This permits high-resolution observation of the sample initial front surface.

Moreover, in FIG. 5, a non-evaporated getter material is used for the ionization chamber. In this example, a getter material 520 is arranged on the wall hit by gas discharged from the ion material gas supply pipe 25. Moreover, the heater 30 is provided on an outer wall of the ionization chamber, and thus before introduction of the ionized gas, the non-evaporated getter material 520 is heated and activated. Then after cooling the ion source to extremely low temperature, the ionized gas is supplied from the ion material gas supply pipe 25. This dramatically reduces impurity gas molecules adhering to the emitter tip and stabilizes the ion beam current, providing an ion beam device capable of sample observation without brightness unevenness present in an observed image.

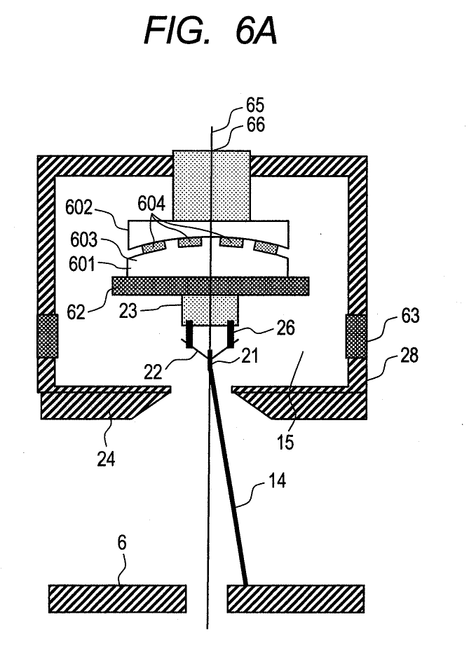

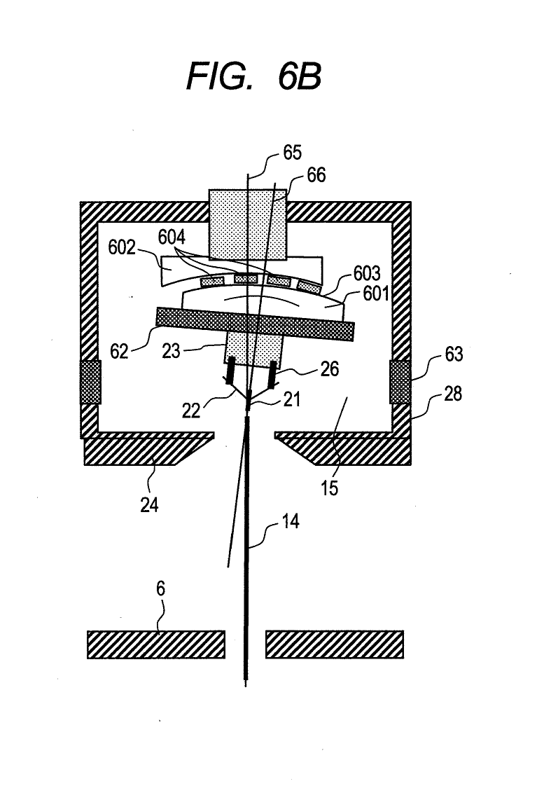

Next, referring to FIG. 6, the tilt mechanism using the piezo element will be described. A central axis line 66 passing through the filament mount 23 can be tilted with respect to a vertical line 65, that is, a central axis line of the gas molecule ionization chamber 15. FIG. 6A shows a state in which the central axis line 66 passing through the filament mount 23 does not tilt with respect to the vertical line 65 (two lines overlap in the figure). FIG. 6B shows a state in which the central axis line 66 passing through the filament mount 23 tilts with respect to the vertical line 65.

The filament mount 23 is fixed to a mobile part 601 of the tilt mechanism. The mobile part 601 is connected to an immobile part 602 with a slide surface 603 in between. This slide surface 603 forms part of a cylindrical surface or a spherical surface with a tip end of the emitter tip 21 as a center, and control of an amount of this sliding permits tilt control with almost no movement of the tip end of the emitter tip 21. Here, “almost” means that a movement of 0.5 mm or below causes no problem. Within this range, adjustment can be made by the deflector. In a case where the slide surface 603 forms part of the cylindrical surface, controlling a rotation angle of this cylindrical surface with an ion beam irradiation axis as a center permits carrying out control of an angle of orientation of a tilted surface. In a case where the slide surface 603 forms part of the spherical surface, the tilt control may be performed with a desired angle of orientation. The slide surface of the tilt means is part of the cylindrical surface or the spherical surface with the tip end of the emitter tip 21 as a center, and thus is not a plane surface. Thus, a small radius of the slide surface from the center of the tip end of the emitter tip 1 to the cylindrical surface or the spherical surface can also provide a small slide surface, downsizing the gas electric field dissociation ion source. Moreover, in the invention, the mobile part 601, the immobile part 602, and the slide surface 603 therebetween are also in the ion source chamber, and the radius of the slide surface is smaller than a radius of a vacuum casing of the ion source. No atmospheric pressure is put on the slide surface, and the mobile part and the immobile part can be downsized and weight-saved. The compact tilt means is stored in the vacuum container of the ion source and further in the ionization chamber, and therefore the ion source itself can also be made compact. That is, it can be downsized and weight-saved. That is, provided is effect that pairing vibration of the charged particle radiation microscope can be intensified and the microscope itself is downsized.

Moreover, a most useful structure of the tilt means in view of manufacture easiness and control easiness has its center axis at the tip end of the emitter 21 and the slide surface having the cylindrical surface with its center at the tip end of the emitter tip 1, and a structure combining two tilt means as cylindrical portion surfaces with mutually different radiuses of the slide surfaces in the two orthogonal directions. The two slide surfaces are relatively rotated through 90 degrees with respect to the ion beam irradiation axis as a center to be combined together along a vertical direction, and independently controlling the two slide surfaces permits tilting in the orthogonal direction, and thus this combination permits tilting in a given direction. In this case, each slide surface may have the piezo elements arranged one dimensionally along a guide on an arch in alignment with the slide direction, thus simplifying the structure and the control. On the other hand, in a case where the slide surface is a spherical surface, although only one slide surface is required, the piezo elements needs to be arranged two-dimensionally on the spherical surface, thus increasing the number of piezo elements and also resulting in very high working accuracy for the arrangement on the spherical surface. Moreover, control of the piezo elements is also complicated.

The piezo elements 604 of FIG. 6 are arrayed along a surface on the mobile part 601 side of the tilt means parallel to the slide surface 603, and the slide surface 603 is firmly attached to these elements. Application of pulse-like voltage to the piezo elements 604 permits extension and contraction of the elements in one direction, making it possible to move the slide surface 603 by frictional force.

Moreover, for a means adapted to generate a tilt force, other than use of the piezo elements described above, for example, a rotation mechanism provided by combination of gears connected to a motor or a push-pull mechanism by a linear actuator can be used.

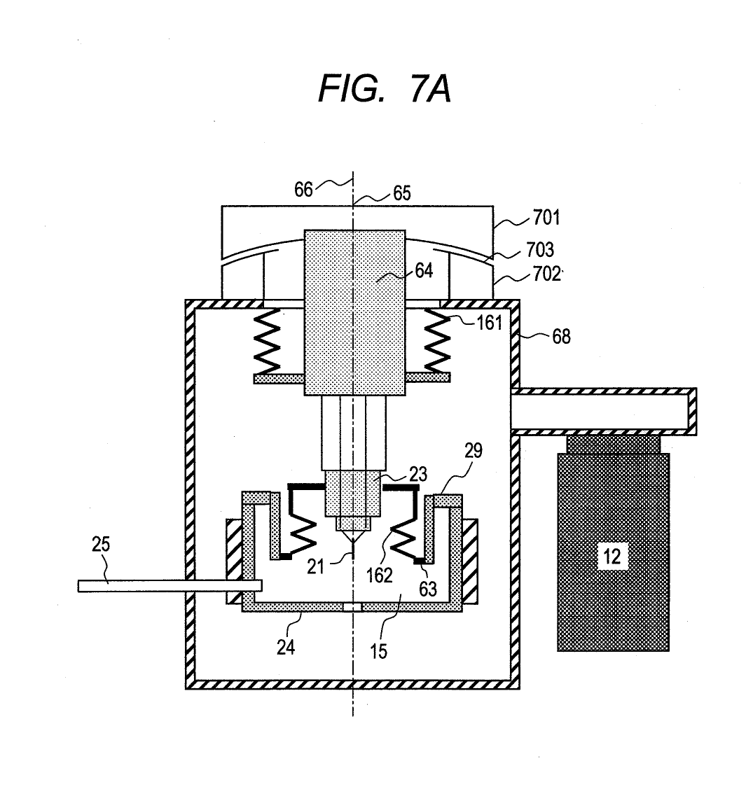

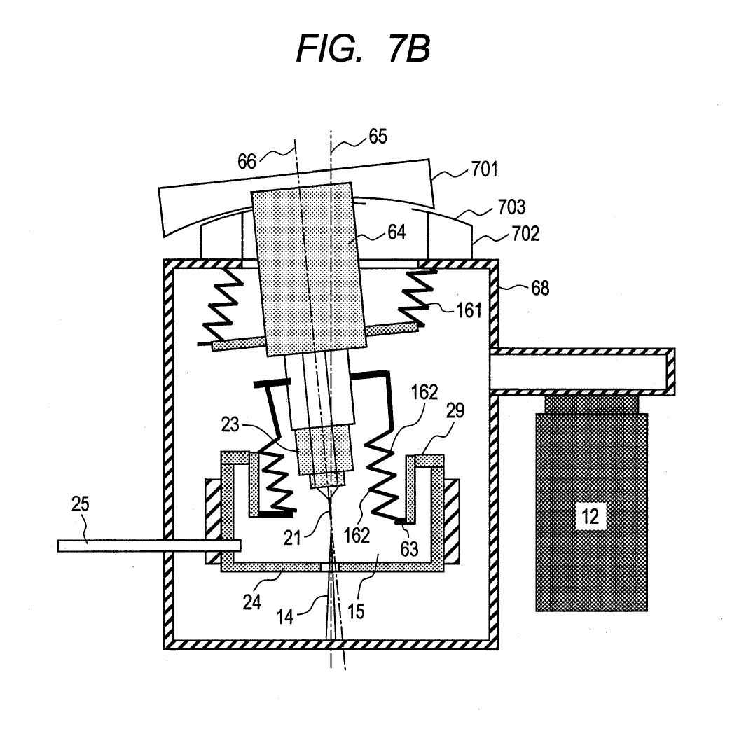

Referring to FIGS. 7A and 7B, another tip tilt mechanism will be described. The central axis line 66 passing through the emitter base mount 64 can be tilted with respect to the vertical line 65, that is, the central axis line of the gas molecule ionization chamber 15. FIG. 7A shows a state in which the central axis line 66 passing through the filament mount 23 and the emitter base mount 64 does not tilt with respect to the vertical line 65 (two lines overlap in the figure). FIG. 7B shows a state in which the central axis line 66 passing through the filament mount 23 and the emitter base mount 64 tilt with respect to the vertical line 65.

In this example, the emitter base mount 64 is fitted to a mobile part 701 of the tilt mechanism, and is connected to a vacuum container 68 with a bellows 161. Moreover, to the top panel 29, the insulation material 63 is connected. Between the insulation material 63 and the filament mount 23, a bellows 162 is fitted. An immobile part 702 is fixed to the vacuum container 68, and the mobile part 701 is connected to the immobile part 702 with a slide surface 703 in between. This slide surface 703 forms part of a cylindrical surface or a spherical surface with the tip end of the emitter tip 21 as a center, and controlling an amount of this sliding permits tilt control with almost no movement of the tip end of the emitter tip 21. In this example, a driving means of the mobile part 701, that is, a means adapted to generate tilt force can be arranged in the air, and therefore there are many choices for this means, for example, a combination of a rotation-direct advance conversion mechanism and a rotary motor.

This structure is characterized in that the emitter tip 21 is connected to the extraction electrode 24 with the deformable bellows 162 and the insulation material 63 in between. As a result, while the extraction electrode is structured to be stationary and the emitter tip 21 is capable of movement including tilting at the same time, periphery of the emitter tip 21 is surrounded, and no helium leaks from areas other than the small hole 27 of the extraction electrode and the gas supply pipe 25. This is because the emitter tip 21 and the extraction electrode 24 are connected together with the deformable bellows 162 in between, providing effect that the air-tightness of the gas molecule ionization chamber improves. Note that the metal bellows is used in this example, but the same effect is also provided by making the connection with a deformable material such as rubber. Moreover, the ionization chamber whose emitter tip is substantially surrounded by the emitter base mount, a shape-changeable mechanism component, the extraction electrode, etc. is characterized by being deformable in the vacuum container. Further, this ionization chamber is characterized by being not in contact with the vacuum container substantially at the room temperature. This results in high ion beam focusing performance and further a high degree of sealing of the gas molecule ionization chamber, which can realize high gas pressure of the gas molecule ionization chamber.

Next, operation of the electric field dissociation ion source of this example will be described. The inside of the vacuum container is evacuated by the ion source evacuating pump 12. The degasing of the extraction electrode 24, the side walls 28, and the top panel 29 is performed by the resistive heater 30. That is, the extraction electrode 24, the side walls 28, and the top panel 29 are heated to be degassed. At the same time, another resistive heater may be arranged outside of the vacuum container and this vacuum container may be heated. This improves a degree of vacuum in the vacuum container and reduces concentration of remaining gas. This operation can improve time stability of ion emission current.

Upon completion of the degassing, the heating by the resistive heater 30 is stopped, and after passage of sufficient time, the freezer is driven. This cools the emitter tip 21, the extraction electrode 24, etc. Next, ionized gas is introduced to the gas molecule ionization chamber 15 by the gas supply pipe 25. The ionized gas is helium or hydrogen, and the description here is based on the assumption that it is helium. As described above, the inside of the gas molecule ionization chamber has a high degree of vacuum. Therefore, a ratio of the ion beam generated by the emitter tip 21 and hitting the remaining gas in the gas molecule ionization chamber to be neutralized decreases. Thus, an ion beam of great current can be generated. Moreover, the number of hot helium gas molecules hitting the extraction electrode decreases. Thus, temperature to which the emitter tip and the extraction electrode are cooled can be lowered. Therefore, the ion beam of the great current can be irradiated to a sample.

Next, voltage is applied between the emitter tip 21 and the extraction electrode 24. An intense electric field is formed at the tip end of the emitter tip. Much of the helium supplied from the gas supply pipe 25 is pulled to the emitter tip surface by the intense electric field. The helium arrives at the vicinity of the tip end of the emitter tip having a most intense electric field. Thus, the helium goes through electric field dissociation whereby a helium ion beam is generated. The helium ion beam is guided to the ion beam irradiation system via the hole 27 of the extraction electrode 24.

Next, a structure of the emitter tip 21 and a method of fabricating the emitter tip 21 will be described. First, a tungsten wire of approximately 100 to 400 μm in diameter in an axial direction <111> is prepared, and its tip end is shaped sharply. This consequently provides an emitter tip with a tip end having a curvature radius of several tens of nanometers. To the tip end of the emitter tip, platinum is vacuum-evaporated in another vacuum container. Next, a platinum atom is moved to the tip end of the emitter tip under high-temperature heating. This forms a nanometer-order pyramid-type structure formed of the white atom. This is called a nano-pyramid. The nano-pyramid typically has one atom at the tip end and has three or six atom layers therebelow, and has 10 or more atom layers further therebelow.

The thin tungsten wire is used in this example, but a thin molybdenum wire can also be used. Moreover, a platinum coat is used in this example, but a coat of, for example, iridium, rhenium, osmium, palladium, or rhodium can also be used.

In a case where the helium is used as the ionized gas, it is important that evaporation intensity of metal be greater than electric field intensity with which the helium is dissociated. Therefore, the coat of platinum, rhenium, osmium, or iridium is preferable. In a case where the hydrogen is used as the ionized gas, the coat of platinum, rhenium, osmium, palladium, rhodium, or iridium is preferable. Formation of the coats of these kinds of metal can also be achieved by a vacuum evaporation method or plating in a solution.

Moreover, as a method of forming the nano-pyramid at the tip end of the emitter tip, for example, electric field evaporation in vacuum or ion beam irradiation may be used. By such a method, a tungsten atom or molybdenum atom nano-pyramid can be formed at a tip end of the tungsten wire or the molybdenum wire. For example, in the case where the tungsten wire in <111> is used, provided is a characteristic such that the tip end is formed of three tungsten atoms. Independently from this, a similar nano-pyramid may be formed at a tip end of a thin wire of, for example, platinum, iridium, rhenium, osmium, palladium, or rhodium through etching action in vacuum. An emitter tip with a sharp tip end structure of any of such atom orders will be called a nano-tip.

As described above, the emitter tip 21 of the gas electric field dissociation ion source according to this example is characterized by being a nano-pyramid. Adjusting the electric field intensity formed at the tip end of the emitter tip 21 permits generation of a helium ion near one atom at the tip end of the emitter tip. Therefore, an ion discharging region, that is, an ion light source is an extremely narrow region, and equal to or smaller than a nanometer. As described above, ion generation from the very limited region can provide a beam diameter equal to or smaller than 1 nm. Thus, current value per unit area and unit solid angle of the ion source increases. This is a very important characteristic for providing on the sample an ion beam of a minute diameter and great current.

Especially in a case where platinum is evaporated to tungsten, a pyramid structure with one atom present at the tip end is stably formed. In this case, a helium ion generating section is focused on vicinity of one atom at the tip end. In case of the tungsten <111> with three atoms at the tip end, helium ion generating sections are dispersed at vicinity of the three atoms. Therefore, an ion source having a platinum nano-pyramid structure where helium gas is collectively supplied to one atom can have greater current discharged from the unit area and the unit solid angle. That is, providing an emitter tip obtained by evaporating platinum to tungsten provides favorable effect for reducing a beam diameter on the sample of the ion microscope and increasing the current. Even use of rhenium, osmium, iridium, palladium, or rhodium, when a nano-pyramid with one atop at the tip end is formed, can similarly increase the current discharged from the unit area and the unit solid angle, and is suitable for reducing the beam diameter on the sample of the ion microscope and increasing the current. However, in a case where the emitter tip is sufficiently cooled and the gas supply is sufficient, it is not necessarily required to form one at the tip end, and satisfactory performance can be exerted even when the number of atoms is, for example, three, seven, or ten.

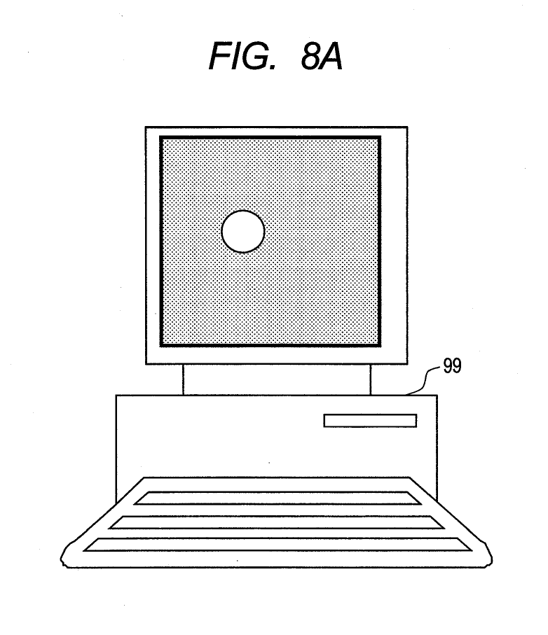

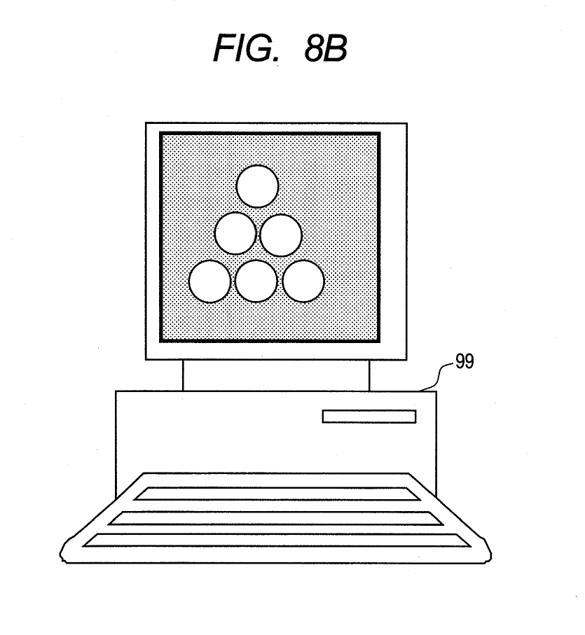

Next, emitter tip tilt angle adjustment will be described. A large opening part of the first aperture is selected. For example, a circular opening part of 3 mm in diameter is selected. That is, provided is condition that all ion beams that have passed through a donut-shaped, discal opening part forming the focusing lens can pass through this opening part of the first aperture. The ion beam that has passed through the first aperture passes through the first deflector, next passes through the first deflector, the second aperture, and the objective lens before arriving at the sample. The secondary particles discharged from the sample, as already described above, are detected by the secondary particle detector 11. The signal from the secondary particle detector 11 is subjected to the luminance modulation and is transmitted to the calculation processor 99. Here, the ion beam is scanned by the first deflector. As a result, of the ion beams discharged from the emitter tip, only the ion beam that has passed through the second aperture arrives at the sample. The secondary particles discharged from the sample as a result of ion beam irradiation are detected by the secondary particle detector 11. The signal from the secondary particle detector 11 is subjected to the luminance modulation and is transmitted to the calculation processor 99. Here, in a case where the emitter tip is a nano-tip having its tip end formed with one atom, the image display device of the calculation processor 99, as shown in FIG. 8A, obtains as an ion radiation pattern a pattern with only one bright section. That is, as the emitter tip tilt angle, an angle with which this bright point can be provided may be set, and referring to a displayed ion radiation pattern image, the emitter tilt angle adjustment and further alignment with the ion beam optical axis can also be performed.

As described above, in a case where almost all the ion beams are provided from only one atom at the tip end, the gas supply is concentrated on one atom, providing a characteristic such that especially an ion source with high luminance is realized compared to, for example, a case of three or more atoms. In the case of one atom at the tip end, it is not required to block ion emission from another atom by the aperture, and there is no need of selecting an atom from the ion radiation pattern.

As described above, according to this example, the ion radiation pattern can be obtained from the emitter tip, making it possible to perform the emitter tilt angle adjustment and the alignment with the ion beam optical axis. Moreover, a ion beam optical system can be shortened, thus resulting in a small amplitude of relative vibration between the emitter and the sample, which consequently permits high-resolution sample observation.

Further, restricting the ion beam passing through the objective lens by the second aperture makes it easy to take the ion beam radiation pattern, which therefore makes it easy to increase the resolution.

Moreover, in a case where the emitter tip is a nano-tip having its tip end formed with a plurality of atoms, for example, 6 atoms, under condition that an area or a diameter of an ion beam discharged from periphery of one atom at the tip end of the emitter tip is at least equal to or larger than an area or a diameter of the opening part of the second aperture, ion beams from the plurality of atoms of the emitter tip can be separated from each other before arriving at the sample. That is, this means that a pattern of the ion radiation from the emitter tip can be observed. This ion radiation pattern is displayed at the image display part of the calculation processor 99, as shown in FIG. 8B. The angle of the emitter tip is adjusted while observing this ion radiation pattern. Specifically, from the ion radiation pattern, one desired bright point or a plurality of bright points are selected from six bright points, and the angle of the emitter tip is adjusted so that the selected bright point(s) arrive(s) at the sample. Note that the ion radiation pattern is not limited to the six-atom pattern as shown in FIG. 8B but typically 3-, 10-, or 15 or more-atom pattern are provided. It was found that, especially in a case where the ion radiation is performed in a state in which 4 to 15 atoms are at the tip end, the current is smaller than that in a case where one to three atoms are provided, but the ion emission is performed stably. That is, the ion current is stabilized, providing effect that an ion source with a long life is realized.

Alternatively, image information of this ion radiation pattern is, even when not image-displayed, stored into the arithmetic device of the calculation processor, and for example, through image analysis of the ion radiation pattern, position and angle of the emitter tip or voltage of the first deflector can also be adjusted based on results of the analysis. Moreover, when the objective lens is formed of a plurality of donut-shaped discal electrodes, using the second aperture also as an electrode forming the objective lens can provide the same function. At this point, this function can be provided by any of the plurality of donut-shaped discal electrodes, but using the electrode closest to the emitter tip as the second aperture results in less secondary electron generation in the objective lens than that when the different electrode is used, providing effect that device unsteadiness due to electric discharge can be avoided.

Moreover, next adjusting DC voltage of the first deflector to align the ion beam with an axis of the objective lens can realize favorable condition for thinning the ion beam. Next, the sample stage is driven to thereby move the sample to be actually observed to a region where ion beam irradiation is possible. Next, the ion beam can be scanned and deflected by the second deflector located more closely to the objective lens than the first deflector and is irradiated to the sample, and the secondary particles discharged from the sample can be detected by the secondary particle detector 11, thereby providing a scanning ion microscope image on a front surface of the sample to be observed.

Moreover, it was found that at position of the second aperture, an ion radiation pattern with a high signal-noise ratio can be provided by applying voltage to the focusing lens and focusing the ion beam in this example so as to satisfy the condition that the area or the diameter of the ion beam discharged from the periphery of one atom at the tip end of the emitter tip is at least equal to or larger than the area or the diameter of the opening part of the second aperture. This requires that voltage condition of the focusing lens is at least under-focus condition for condition of ion beam focus onto the opening part of the second aperture.

Moreover, it was found that if an area of the opening part of the first aperture when the ion radiation pattern is obtained is larger than the area of the opening part of the second aperture, an ion radiation pattern in a sufficiently wide range for the pattern analysis is provided.

Moreover, it was found that if the area of the opening part of the first aperture when the ion radiation pattern is obtained is larger than the area of the opening part of the first aperture when the ion beam on the sample is thinned to 10 nm or less at a maximum, an ion radiation pattern in a sufficiently wide range for the pattern analysis is provided.

Moreover, if an area for ion beam scanning by the first deflector at the second aperture position is at least four times the area of the opening part of the second aperture, an ion radiation pattern with favorable resolution is provided.

Moreover, in this example, a means adapted to measure a signal volume substantially proportional to ion beam current that has passed through the second aperture is a means adapted to detect by the secondary particle detector 11 the secondary particles discharged from the sample, but the same function can be provided even by a different means including any of an ammeter measuring the ion beam current, for example, an ammeter connected to the sample, a means adapted to amplify the ion beam current for measurement, and a means adapted to perform amplification with a multi-channel plate for measurement, that is, the ion radiation pattern can be observed, and the signal-noise ratio in particular can be increased for the observation.

Moreover, in this example, providing shorter space from a lower end of the focusing lens to the first aperture than length of the first deflector can eliminate unnecessary space in an optical length of the irradiation system and also can provide an ion emission pattern and further can shorten the optical length. That is, according to the invention, provided in the charged particle radiation device provided with the gas electric field dissociation ion source is effect that the ion irradiation system becomes compact, the ion optical length is shortened, and the amplitude of the relative vibration between the emitter tip and the sample decreases, making it possible to perform high-resolution sample observation. Also provided is effect that a direction of ion discharge from the emitter tip can be adjusted to a direction towards the sample with high accuracy and thereby a charged particle radiation device maximizing performance of the gas electric field dissociation ion source can be realized.

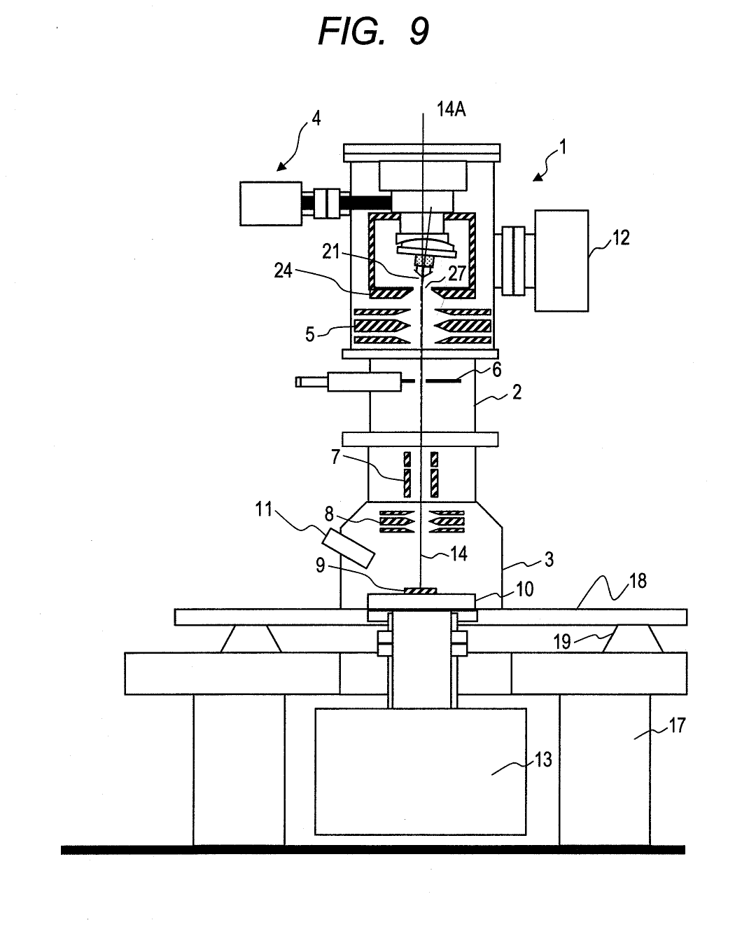

Next, referring to FIG. 9, as one example of the invention, a description will be given concerning a charged particle radiation device which mechanically changes a tilt angle of the ion emitter with respect to the ion beam irradiation axis to observe the pattern of the ion radiation from the ion emitter. Included in this device are: as already described above, the emitter tip 21 of a needle-like shape; the gas electric field dissociation ion source 1 including the extraction electrode 24 which is provided oppositely to the emitter tip and which has the opening part through which ions pass; the focusing lens 5 focusing the ions discharged from the ion source; the mobile aperture 6 restricting the ion beam 14 that has passed through the focusing lens; a deflector 7 deflecting the ion beam 14 that has passed through the aperture; the objective lens 8 focusing onto the sample the ion beam that has passed through the deflector; the secondary particle detector 11 detecting the secondary particles discharged from the sample 9 as a result of irradiation of the ion beam 14; etc. Included here is the tilt mechanism capable of tilting the emitter tip 21 with respect to the ion beam irradiation axis with the tip end of the emitter tip as substantially a tilt axis.

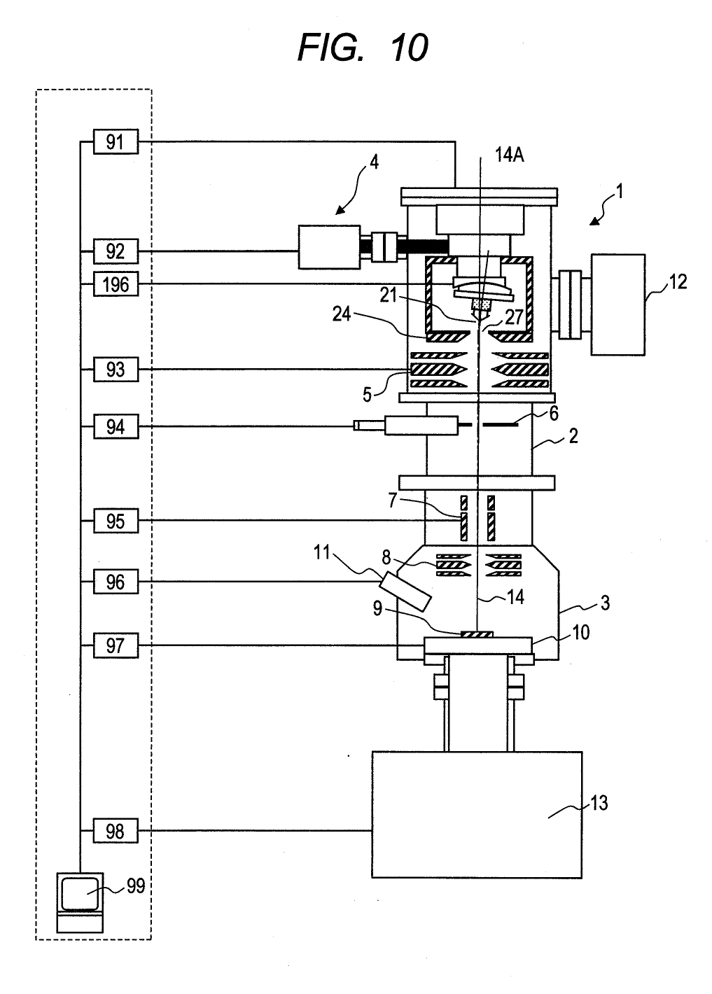

FIG. 10 shows the controllers of this example. The controllers of this example include: the electric field dissociation ion source controller 91 which controls the gas electric field dissociation ion source 1; a tip tilt mechanism controller 196 which controls the emitter tip tilt mechanism; the lens controller 93 which controls the focusing lens 5 and the objective lens; the aperture controller 94 which controls the mobile aperture 6; the deflector controller 95 which controls the deflectors; the secondary electronic detector controller 96 which controls the secondary particle detector 11; the sample stage controller 97 which controls the sample stage 10; the evacuating pump controller 98 which controls the sample chamber evacuating pump 13; and the calculation processor 99 including the arithmetic device, and the calculation processor 99 includes the image display part. The image display part displays the image generated from the detection signal of the secondary particle detector 11 and the information inputted by the input means.

The mobile aperture has a mechanism of moving the aperture in the two orthogonal directions within the plane substantially perpendicular to the ion beam irradiation axis. This control is executed by the mobile aperture controller 97 based on the command from the calculation processor 99.

Operation of the ion beam irradiation system of the ion microscope of this example will be described. The operation of the ion beam irradiation system is controlled by the commands from the calculation processor 99. The ion beam 14 generated by the gas electric field dissociation ion source 1 is focused by the focusing lens 5, passes through the mobile aperture 6, and is focused by the objective lens 8. The focused beam is irradiated while scanned onto the sample 9 on the sample stage 10.

The secondary particles discharged from the sample are detected by the secondary particle detector 11. The signal from the secondary particle detector 11 is subjected to the luminance modulation and is transmitted to the calculation processor 99. The calculation processor 99 generates a scanning ion microscope image and displays it at the image display part. In this manner, high-resolution observation of the sample front surface can be realized.

Next, emitter tip angle adjustment in this device will be described. For the opening part of the mobile aperture, for example, a circular opening part of 0.01 mm in diameter is selected. Next, through the control of the tip tilt mechanism controller 196, an angle of tilting of the emitter tip with respect to the ion beam irradiation axis is gradually changed. Here, only when the ion beam discharged from the emitter tip has passed through the mobile aperture, arrival at the sample 9 occurs. The secondary particles discharged from the sample as a result of the ion beam irradiation are detected by the secondary particle detector 11. The signal from the secondary particle detector 11 is subjected to the luminance modulation and is transmitted to the calculation processor 99. Here, in the case where the emitter tip is a nano-tip having its tip end formed with one atom, a pattern with only one bright section is provided as the ion radiation pattern in the image display device of the calculation processor 99. That is, as the emitter tip tilt angle, the angle with which this bright point can be provided may be set. That is, referring to the displayed ion radiation pattern image, the emitter tilt angle adjustment and further the alignment with the ion beam optical axis can also be done.

Moreover, in the case where the emitter tip is a nano-tip having its tip end formed with a plurality of atoms (for example, six atoms), at the mobile aperture position, under condition that the ion beam discharged from the periphery of one atom is at least equal to or larger than the opening part at the mobile aperture position, the ion beams respectively from the plurality of atoms of the emitter tip can be separated from each other before arriving at the sample. This means that gradually changing the emitter tip tilt angle with respect to the ion beam irradiation axis permits the observation of the pattern of the ion radiation from the emitter tip. This ion radiation pattern is displayed at the image display part of the calculation processor. While observing this ion radiation pattern, the emitter tip angle is adjusted. That is, from the ion radiation pattern, a desired one bright point or a plurality of bright points may be selected from six bright points and the emitter tip angle may be adjusted so that this arrives at the sample.

Alternatively, image information of this ion radiation pattern, even when not image-displayed, is stored into the arithmetic device of the calculation processor, and for example, the ion radiation pattern can be subjected to image analysis, and based on results of this analysis, the emitter tip angle can be adjusted.

Moreover, it was found that an ion radiation pattern with a high signal-noise ratio is provided by applying voltage to the focusing lens to focus the ion beam in this example so as to satisfy condition that at the mobile aperture position, the area or the diameter of the ion beam discharged from the periphery of one atom at the tip end of the emitter tip is at least equal to or larger than the area or the diameter of the opening part of the mobile aperture. This requires that the voltage condition of the focusing lens is at least under focus condition for condition of the ion beam focus onto the opening part of the mobile aperture.

Moreover, instead of the mobile aperture, a fixed aperture can be arranged between the deflector and the objective lens and the ion radiation pattern can be observed by use of this to adjust the emitter tip. In this case, it is suitable for aligning the ion beam with the axis of the objective lens, and reducing aberration of the objective lens can provide a more minute ion beam diameter, that is, ultrahigh-resolution observation can be performed.

In case of this example, since the deflector is not used for providing the ion radiation pattern, the configuration of the controllers is simplified, providing effect that the costs can be reduced. Moreover, in this example, providing a shorter interval between the lower end of the focusing lens to the mobile aperture than the length of the deflector can eliminate unnecessary space in the optical length of the irradiation system and also provide an ion emission pattern, and further shorten the optical length. That is, according to the invention, provided in the charged particle radiation device provided with the gas electric field dissociation ion source is effect that the ion irradiation system becomes compact, the ion optical length is shortened, thereby the amplitude of the relative vibration between the emitter tip and the sample decreases, and the high-resolution sample observation becomes possible. Also provided is effect that a charged particle radiation device capable of accurately adjusting the direction of the ion discharge from the emitter tip to the direction towards the sample to thereby maximize the performance of the gas electric field dissociation ion source can be realized.

Next, referring to FIG. 9, as one example according to the invention, a charged particle radiation device which observes the pattern of the ion irradiation from the ion emitter by use of a means adapted to move the mobile aperture position within the plane substantially perpendicular to the ion beam will be described. First, the center of the opening part of the mobile aperture is matched with the ion beam irradiation axis, and also, for example, a circular opening part of 0.01 mm in diameter is selected as the opening part of the mobile aperture. Next, through control by the mobile aperture controller, the mobile aperture position is scan-moved in the two orthogonal directions within the plane substantially perpendicular to the ion beam irradiation axis. Here, the ion beam discharged from the emitter tip arrives at the sample only when it passes through the mobile aperture. The secondary particles discharged from the sample as a result of the ion beam irradiation are detected by the secondary particle detector 11. The signal from the secondary particle detector 11 is subjected to the luminance modulation, and is transmitted to the calculation processor 99. Here, in the case where the emitter tip is a nano-tip having its tip end formed with one atom, in the image display device of the calculation processor, a pattern with only one bright section as is provided as the ion radiation pattern. Then this pattern is observed while gradually varying the tilt angle of the emitter tip with respect to the ion beam irradiation axis. Then if a luminous point is at a center of the image, this means that the emitter tip tilt angle could be adjusted.

Moreover, in the case where the emitter tip is a nano-tip having its tip end formed with a plurality of atoms (for example, six atoms), under condition that the ion beam discharged from the periphery of one atom is at least equal to or larger than the opening part at the mobile aperture position, the ion beams respectively from the plurality of atoms of the emitter tip can be separated from each other before arriving at the sample. This means, as is the case with the above, that scan and moving the mobile aperture position in the two orthogonal directions within the plane substantially perpendicular to the ion beam irradiation axis permits observation of the pattern of the ion radiation from the emitter tip. The emitter tip angle is adjusted while this ion radiation pattern is observed. That is, from the six luminous points in the ion radiation pattern, one desired luminous point or the plurality of luminous points may be selected, and the emitter tip angle may be adjusted so that this arrives at the sample.

Alternatively, even in a case where the image information of this ion radiation pattern is not image-displayed, it can be stored into the arithmetic device of the calculation processor, and for example, image analysis of the ion radiation pattern can be performed, and based on results of this analysis, the emitter tip angle can be adjusted.

In the example described above, the mobile aperture or the fixed aperture is used, but a slit may also be used. For example, use of two sets of slits arranged in the two orthogonal directions makes it possible to adjust X and Y directions independently from each other.

Described in the example above is a case where the ion radiation pattern image is a two-dimensional image, but it may be a unidirectional secondary particle intensity profile. In this case, on the image display device of the calculation processor, the secondary particle intensity profile may be displayed.

In the example described above, the adjust sample upon the ion radiation pattern observation preferably has substantially constant secondary particle generation efficiency in almost all flat regions where the ion beam is irradiated. For example, the adjusting sample is preferably a mono-crystal sample such as a silicon mono-crystal wafer or stainless steel whose surface is polished. This enables observation of the pattern of the ion radiation from the emitter tip in an even state. Moreover, at time of the emitter tip tilt angle adjustment, the sample stage is moved and the adjust sample is arranged in the ion beam irradiation region for the ion radiation pattern observation, thereby preventing ion beam irradiation to the object to be observed. Then upon the sample observation, through the sample stage movement, the target sample may be arranged in the ion beam irradiation region. This provides effect that the sample to be observed at time of the axis adjustment is hardly contaminated and broken.

Moreover, in the example described above, a means adapted to measure the signal volume substantially proportional to the ion beam current that has passed through the mobile aperture is a means adapted to detect the secondary particles discharged from the sample by the secondary particle detector 11, but the same function can be provided, that is, the ion radiation pattern can be observed by a different means including any of: an ammeter measuring the ion beam current, for example, an ammeter connected to the sample, a means adapted to amplify the ion beam current with channel thoron for measurement, and a means adapted to amplify it with a multichannel plate for the measurement. This provides effect that a radiation pattern with an especially high signal-noise ratio can be provided.

Moreover, the second aperture can also serve as an electrode forming the objective lens. That is, use of the opening part of the objective lens as the second aperture provides effect that the components can be commonized.

Described in the example above as the charged particle radiation device capable of observing the pattern of the ion radiation from the ion emitter of the gas electric field dissociation ion source are: (1) a device having the fixed aperture below the first deflector and the second deflector and having a means adapted to scan the ion beam by the first deflector; (2) a device having a means adapted to mechanically change the ion emitter tile angle with respect to the ion beam irradiation axis; and (3) a device having a means adapted to move the mobile aperture position within the plane substantially perpendicular to the ion beam, but two or three of them may be combined together. This provides effect that a device with a wide pattern observation region, high pattern analysis accuracy, and favorable emitter tip angle adjustment accuracy can be formed.

Moreover, an example in which these means are used for the emitter tip angle adjustment has been described, but they may be used for emitter tip position adjustment. This provides effect that an extremely minute ion beam with high accuracy in the adjustment with the ion beam irradiation axis and small lens distortion aberration can be formed, that is, ultrahigh-resolution observation and highly accurate machining can be performed.

In the example described above, according to the invention, provided is effect that, in the charged particle radiation device provided with the gas electric field dissociation ion source, the iron irradiation system becomes compact, the ion optical length becomes short, thereby the amplitude of the relative movement between the emitter tip and the sample becomes small, and the high-resolution sample observation can be performed. Also provided is effect that the direction of the ion discharge from the emitter tip can accurately be adjusted to the direction towards the sample, thereby realizing the charged particle radiation device that maximize the performance of the gas electric field dissociation ion source.

Also provided according to the invention is effect that the ion beam is stabilized in the charged particle radiation device provided with the gas electric field dissociation ion source.

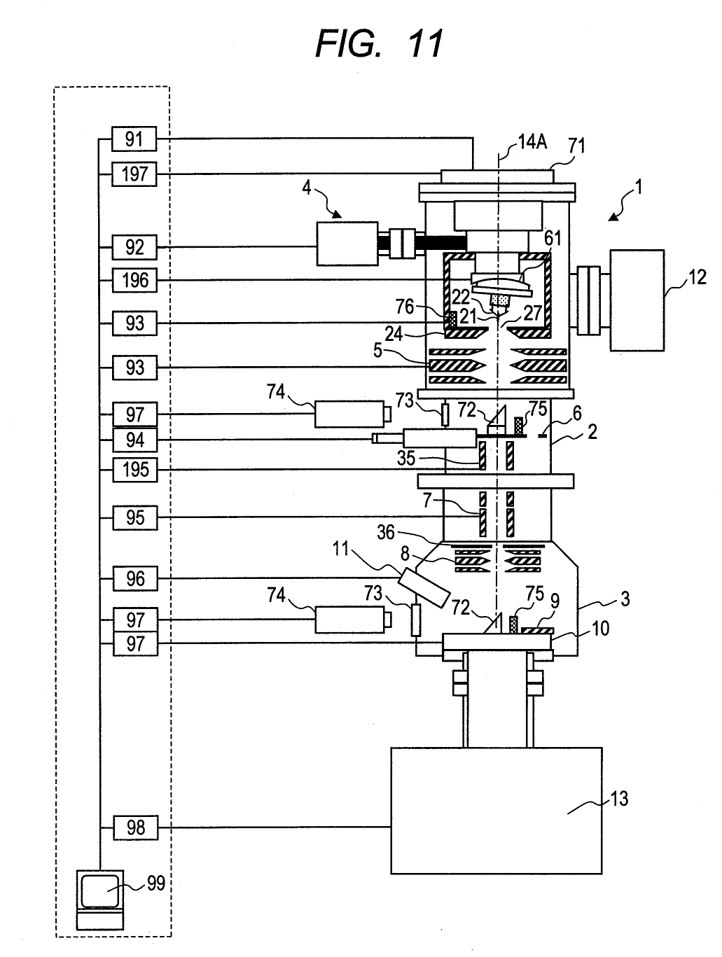

Referring to FIG. 11, as one example according to the invention, a charged particle radiation device provided with a means adapted to light discharged form or reflected from an emitter or a filament connected to the emitter through the opening part of the extraction electrode will be described. This device is composed of: an emitter tip 21 of a needle-like shape; a gas electric field dissociation ion source 1 including an extraction electrode provided oppositely to the emitter tip 21 and having an opening part through which ions pass; a focusing lens 5 focusing the ions discharged from the ion source; a mobile aperture 6 restricting an ion beam that has passed through the focusing lens 5; a deflector 7 deflecting the ion beam that has passed through the aperture; an objective lens 8 focusing onto a sample 9 the ion beam that has passed through the deflector; a secondary particle detector 11 detecting secondary particles discharged from the sample; etc. Here, the emitter tip 21 includes: a plane movement mechanism 71 capable of moving within a plane substantially perpendicular to a direction in which the ion beam is drawn from the ion source; and a tilt mechanism 61 capable f tilting the emitter tip with respect to the ion beam irradiation axis with a tip end of the emitter tip as a tilt axis. Moreover, a sample stage 10 has a moving function 71 within a plane perpendicular to the ion beam. Moreover, onto the sample stage 10, a light path change means such a prism, an optical fiber, or a reflecting mirror 72 is fitted. Light from a direction of the ion beam irradiation axis is reflected in a substantially perpendicular direction. Moreover, included in a vacuum container of a sample chamber is a view port 73 through which the light passes.

Controllers of this example has: an electric field dissociation ion source controller 91 controlling the gas electric field dissociation ion source 1; a tip position movement controller 197 controlling an emitter tip position movement mechanism; a tip tilt movement controller 196 controlling the emitter tip tilt movement mechanism; a lens controller 93 controlling the focusing lens 5 and the objective lens; an aperture controller 94 controlling the mobile aperture 6; a deflector controller 95 controlling the deflector; a secondary electron detector controller 96 controlling the secondary particle detector 11; a sample stage controller 97 controlling the sample stage 10; an evacuating pump controller 98 controlling a sample chamber evacuating pump 13; and a calculation processor 99 including an arithmetic device. The calculation processor 99 includes an image display part. The image display part displays an image generated from a detection signal of the secondary particle detector 11 and information inputted by an input means.

First, as one example of the invention, a charged particle radiation device making axis alignment between the emitter tip and the opening part of the ion extraction electrode by light discharged or reflected from the emitter tip or a filament connected to the emitter tip will be described.

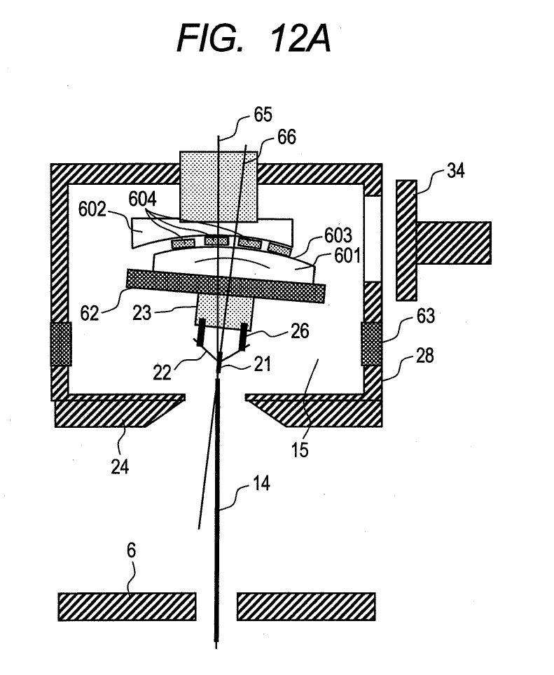

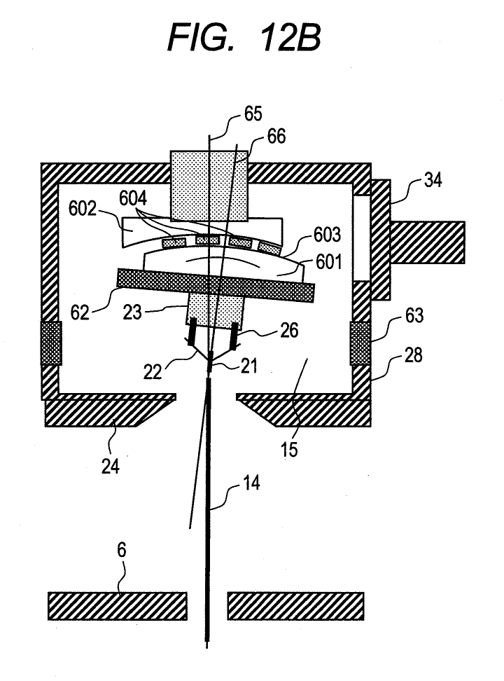

Voltage is applied to the filament 22 connected to the emitter tip 21 by the gas electric field dissociation ion source to heat the filament and discharge light. As a result, from the opening part 27 of the extraction electrode, the light discharged or reflected from the filament and the emitter tip is emitted. A travel path of this light is changed to a perpendicular direction by the light path change means such as the prism, the light fiber, or the reflecting mirror 72, and this is detected through the view port fitted to the vacuum container of the sample chamber. For example, it is observed with an optical camera 74. This enables observation of a shadow of the opening part 27 of the extraction electrode as shown in FIG. 12 and the filament 22 and the emitter tip 21 fitted to the filament. That is, relative position of the emitter tip 21 and the opening part 27 of the extraction electrode can be recognized. Then while observing this image, the emitter tip is moved to a center of the opening part of the extraction electrode. Alternatively, this image information is analyzed by the calculation processor 99, and by the emitter tip position movement controller 197, the emitter tip is moved to the center of the opening part of the extraction electrode. This makes it possible to make the axis alignment between the emitter tip and the opening part of the extraction electrode. This reduces disturbance of an ion beam orbit at the opening part of the extraction electrode, providing effect that the ion beam can be focused into an extremely minute beam, that is, ultrahigh-resolution observation or highly accurate machining can be done.

Next, upon the sample observation, by moving the sample stage within the plane substantially perpendicular to the ion beam irradiation axis, the target sample 9 may be arranged in the ion beam irradiation region. Described in this example is an example in which the light path change means such as the prism, the light fiber, or the reflecting mirror is arranged on the sample stage 10, but the prism, the light fiber, or the reflecting mirror 72 may be arranged on the mobile aperture 6. That is, at time of the axis alignment between the emitter tip and the opening part of the ion extraction electrode, the mobile aperture 6 is moved to arrange the light path change means such as the prism, the optical fiber, or the reflecting mirror 72 onto the ion beam irradiation axis. As a result, through the view port 73 fitted to the vacuum container of the irradiation system column, the light discharged or reflected from the emitter tip or the filament connected to the emitter tip may be detected. For example, it is observed by the optical camera 74. In this case, compared to the case where the arrangement onto the sample stage is made, the observation can be made closely to the emitter tip, thus providing effect that adjustment of the axis alignment can be made with even higher accuracy. Then at end of the adjustment of the axis alignment between the emitter tip and the opening part of the extraction electrode, the mobile aperture may be moved and the ion beam may be passed with the aperture opening part in alignment with the ion beam irradiation axis to observe the sample.

Further, a mobile shutter may be provided between the focusing lens 5 and the objective lens 8, and onto this mobile shutter, the light path change means such as the prism, the light fiber, or the reflecting mirror may be arranged. That is, at the time of the axis alignment between the emitter tip and the opening part of the ion extraction electrode, the mobile shutter may be moved to arrange the light path change means such as the prism, the light fiber, or the reflecting mirror onto the ion beam irradiation axis. As a result, through the view port fitted to the vacuum container of the irradiation system column, the light discharged or reflected from the emitter tip or the filament connected to the emitter tip may be detected.

Then at the end of the adjustment of the axis alignment between the emitter tip and the opening part of the extraction electrode, the mobile aperture 6 may be moved to remove the shutter from the ion beam irradiation axis 14A, and the ion beam may be passed to observe the sample. In this case, compared to a case where the mobile shutter is arranged between the emitter tip and the focusing lens or between the objective lens and the sample, an ion optical system with smaller lens aberration can be formed, providing effect that the ion beam can be focused into an extremely minute beam, that is, ultrahigh-resolution observation or highly accurate machining can be done.

Moreover, described in the example above is an example in which the light discharged or reflected from the filament connected to the emitter tip is guided by using the light path change means such as the prism, the light fiber, or the reflecting mirror 72 to outside of the vacuum container and this light is then detected, but a light detection device 75 may be arranged in the vacuum container and signal information from the light detection device may be transmitted to the outside of the vacuum container. For example, the light detection device may be on the sample stage, the mobile aperture. Alternatively, a mobile shutter may be provided between the focusing lens 5 and the objective lens 8 and the light detection device may be on this.

Moreover, described in the example above is an example in which the light discharged or reflected from the emitter tip or the filament connected to the emitter tip is used for the adjustment of the axis alignment between the emitter tip and the opening part of the extraction electrode, but it may be used for emitter tip temperature control. That is, provided is a charged particle radiation device provided with a controller which controls at least one of voltage applied to the filament, current, resistance, and temperature by using a signal obtained by detecting, through the opening part of the extraction electrode, the light discharged or reflected from the emitter tip or the filament connected to the emitter tip.

Performed in the emitter tip of the gas electric field dissociation ion source is high-temperature anneal processing for surface contamination removal or emitter tip end crystal condition control, nano-pyramid formation control. The inventor of this application found that controlling this temperature with high accuracy is required for stabilization of the ion beam from the emitter tip or lengthening life of the emitter tip. He/she found that especially at time of cooling the emitter tip 21 to extremely low temperature, under the influence of ambient temperature, it is difficult to make sufficient temperature control only through, for example, a control of maintaining constant power of the filament connected to the emitter tip. Thus, temperature measurement is useful, but since the high voltage is applied to the emitter tip, it is difficult to make temperature measurement in a contact state. Moreover, for the gas electric field dissociation ion source, for the purpose of increasing gas pressure around the emitter tip, the emitter tip excluding the opening part of the extraction electrode is desirably structured to be sealed, and it has also been difficult to make temperature measurement in a non-contact state by use of the light discharged from the emitter tip. Thus, provided in the invention is the charged particle radiation device provided with a means adapted to detect through the opening part of the extraction electrode the light discharged or reflected from the emitter or the filament connected to the emitter. That is, provided is the charged particle radiation device provided with the controller controlling at least one of the voltage applied to the filament, the current, the resistance, and the temperature by using the signal obtained through the light detection. This makes it possible to perform temperature control with high accuracy even at time of the cooling to the extremely low temperature, realizes highly accurate temperature control in the high-temperature treatment of the emitter tip, realizes the stabilization of the ion beam from the emitter tip or lengthening the life of the emitter tip, and also realizes, for example, greater current of the ion beam at the same time. Then provided is effect that reliability and performance of the gas electric field dissociation ion source improve.

Moreover, an object of the highly accurate emitter tip temperature control is achieved by providing the charged particle radiation device which arranges, in the gas molecule ionization chamber 15 storing gas around the ion emitter, a means adapted to detect the light discharged or reflected from the emitter or the filament connected to the emitter and which is provided with a means adapted to transmit detection information to outside of the vacuum container. In this case, the arrangement can be done closely to the emitter, thus providing effect that even more highly accurate temperature measurement can be performed, but the arrangement is done around the emitter to which the high voltage is applied, thus presenting a problem that costs for providing a mechanism of preventing, for example, electric discharge increase.

In the example described above, the invention provides effect that in the charged particle radiation device provided with the gas electric field dissociation ion source, in terms of the axis adjustment of the ion irradiation system, the adjustment of the axis alignment between the emitter tip and the opening part of the extraction electrode can be made and aberration occurring upon ion beam thinning can be reduced to realize an ultrafine beam.

Moreover, according to the invention, in the charged particle radiation device provided with the gas electric field dissociation ion source, also at the time of cooling the emitter tip to the extremely low temperature, highly accurate temperature control can be made, the highly accurate temperature control is realized in the emitter tip high-temperature treatment, the stabilization of the ion beam from the emitter tip or the lengthening of the life of the emitter tip is realized, and also, for example, greater current of the ion beam is realized at the same time. Then provided is effect that the reliability and the performance of the gas electric field dissociation ion source improve.

In a case where the nano-pyramid is damaged by, for example, an unanticipated electric discharge phenomenon, the emitter tip is heated for approximately 30 minutes (approximately 1000 degrees Celsius). This makes it possible to reproduce the nano-pyramid. That is, the emitter tip can easily be mended. Thus, a practical ion microscope can be realized.

Distance between the tip end of the objective lens 8 and a front surface of the sample 9 is referred to as working distance. In this ion beam device, where the working distance is less than 2 mm, resolution is less than 0.5 nm, realizing super-resolution. Conventionally, since an ion of, for example, gallium is used, spatter particles from the sample contaminate the objective lens, raising concern that normal operation may be interrupted. The ion microscope according to the invention can provide ultrahigh resolution with little concern described above.

Described in this example is an example in which a freezer is applied for the cooling mechanism 4, but permitted is a cooling mechanism including a cooling tank and using a cryogen such as liquid nitrogen or liquid helium. Especially, after the liquid helium is introduced to the cooling tank, inside of the cooling tank is evacuated through an evacuation port. As a result, the liquid nitrogen is solidified to provide solid nitrogen. When the solid nitrogen is used, vibration attributable to boiling of the liquid nitrogen does not occur. That is, the cooling mechanism does not cause mechanical vibration. Thus, provided is effect that high-resolution observation can be performed.

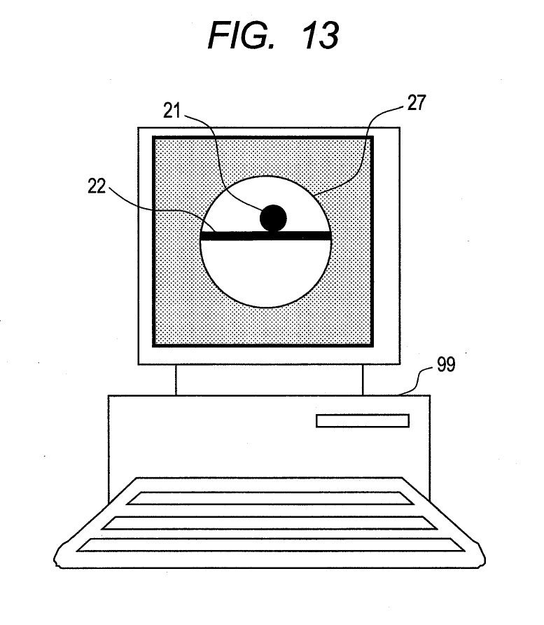

In this example, an open-close valve opening and closing the gas molecule ionization chamber 15 is fitted. The open-close valve has a cover member 34. FIG. 12A shows a state in which the cover member 34 is open, and FIG. 13B shows a state in which the cover member 34 is closed.

Operation of the gas electric field dissociation ion source of this example will be described. First, as shown in FIG. 12A, in the state in which the cover member 34 of the gas molecule ionization chamber 15 is open, rough evacuation is performed. Since the cover member 34 of the gas molecule ionization chamber 15 is open, the rough evacuation in the gas molecule ionization chamber 15 is completed in short time.

With this example, providing the cover member 34 in the gas molecule ionization chamber 15 makes it possible to increase conductance at time of vacuum roughing even if a dimension of the hole of the extraction electrode is small. Moreover, reducing the dimension of the hole of the extraction electrode makes it possible to seal the gas molecule ionization chamber 15. Thus, higher vacuum in the gas molecule ionization chamber 15 can be achieved, providing an ion beam with great current.

Moreover, at time of control of a state of the atom pyramid at the tip end of the emitter tip 21 or the high-temperature treatment for reproduction processing, as shown in FIG. 12A, provided is the state in which the cover member 34 of the gas molecule ionization chamber 15 is open. The inventor of this application found that this permits providing ultrahigh vacuum in the inside of the gas molecule ionization chamber 15 at the time of high-temperature treatment, controlling the state of the atom pyramid or improving the reliability of the reproduction processing. That is, provided is effect that increasing the conductance at the time of vacuum roughing when voltage is applied to the filament 22 realizes the lengthening life of the emitter tip.

Moreover, the ion radiation pattern can be observed by providing a scanning electric field ion microscope observation method characterized by scanning by the first deflector the ion beam that has passed through the first aperture, restricting the scanned ion beam by the second aperture, detecting by the charged particle detector the secondary particles discharged from the sample as a result of irradiation of the ion beam, and observing an electric field ion microscope pattern of the nano-tip based on a scanned image using a signal from the detector.

Moreover, a microscope can be made compact by providing a scanning ion microscope observation method characterized by condensing by the focusing lens the ions discharged from the ion source, restricting by the first aperture the ion beam that has passed through the focusing lens, scanning by the second deflector the ion beam that has passed through the first aperture, detecting by the charged particle detector the secondary particles discharged from the sample as a result of irradiation of the scanned ion beam, and observing with the microscope the sample based on a scanned image using a signal from the detector.

Moreover, the ion radiation pattern can be observed by providing the scanning charged particle microscope, which includes: the vacuum container; the ion emitter of a needle-like shape in the vacuum container; the gas electric field dissociation ion source including the extraction electrode provided oppositely to the emitter tip and having the opening part through which the ions pass; the focusing lens focusing the ions discharged from the ion source; the mobile aperture restricting the ion beam that has passed through the focusing lens; the deflector deflecting the ion beam that has passed through the aperture; the objective lens focusing onto the sample the ion beam that has passed through the deflector; and the charged particle detector detecting the secondary particles discharged from the sample as a result of the irradiation of the ion beam, as a charged particle microscope characterized by: including a means adapted to move position of the mobile aperture within the plane substantially perpendicular to the ion beam irradiation axis; and recording intensity of the secondary particles discharged from the sample based on a difference in the position of the mobile aperture to enable the observation of the pattern of the ion radiation from the ion emitter.

Moreover, temperature of the emitter or the filament can be observed by providing the charged particle microscope characterized by including in the vacuum container a means adapted to detect through the opening part of the extraction electrode the light discharged or reflected from the emitter or the filament connected to the emitter.

Moreover, the emitter temperature can be measured by providing the charged particle microscope, which includes: for example, the vacuum container; the ion emitter of a needle-like shape in the vacuum container; the gas electric field dissociation ion source including the extraction electrode provided oppositely to the emitter tip and having the opening part through which ions pass; the focusing lens accelerating and focusing the ions discharged from the ion source; the mobile aperture restricting the ion beam that has passed through the focusing lens; the deflector deflecting in two steps the ion beam that has passed through the aperture; the objective lens focusing onto the sample the ion beam that has passed through the deflector; the sample stage loaded with the sample; the charged particle detector detecting the secondary particles discharged from the sample as a result of the irradiation of the ion beam, as a charged particle microscope characterized by: arranging, in the ionization chamber accumulating gas around the ion emitter, the means adapted to detect the light discharged or reflected from the emitter or the filament connected to the emitter; and including the means adapted to transmit the information of the detection to outside of the vacuum container.

Moreover, provided is the charged particle microscope characterized in that the ions discharged from the ion source is helium ions or hydrogen ions.

Next, a charged particle microscope which irradiates an electron beam to a sample will be described. This charged particle microscope is composed of: a vacuum container; an electron emitter of a needle-like shape in the vacuum container; an electron source which is pro including an extraction electrode provided oppositely to the emitter tip and having an opening part through which an electron passes; a focusing lens focusing the electron discharged from the electron source; a mobile first aperture restricting an electron beam that has passed through the focusing lens; a first deflector scanning or aligning the electron beam that has passed through the first aperture; a second deflector deflecting the electron beam that has passed through the first deflector; a second aperture restricting the electron beam that has passed through the first aperture; an objective lens focusing onto a sample the electron beam that has passed through the first aperture; and a means adapted to measure a signal volume substantially proportional to current of the electron beam that has passed through the second aperture. This provides an scanning electron microscopic image obtained by irradiating the electron beam to the sample.

Moreover, upon electron extraction from the electron emitter, as shown in FIG. 12A, a cover member 34 of a gas molecule ionization chamber 15 is turned into an open state. The inventor of this application found that this can provide ultrahigh vacuum inside of the gas molecule ionization chamber 15 when the electron beam is in use, stabilizes the electron beam, and can also prevent breakdown of the electron emitter.

Further, in the charged particle microscope of this example, an ion beam can be extracted from the emitter tip serving as the electron emitter. This is realized by applying negative high pressure to the emitter tip upon the electron beam extraction and by applying positive high pressure to the emitter tip upon the ion beam extraction. Especially upon the electron beam irradiation to the sample, an X-ray or an Auger electron discharged from the sample is detected. This makes it easy to perform element analysis of the sample. Further, at this point, an ion image with a resolution of 1 nm or less and an element-analyzed image may be aligned or superposed on each other to be displayed. As a result, the sample surface can be favorably subjected to characterization.

Moreover, at this point, using a compound lens combining a magnetic sector-type lens and an electrostatic lens as the objective lens for condensing the electron beam can focus the electron beam with great current into a minute beam diameter and makes it possible to perform sensitive element analysis with high space resolution.

Moreover, a relatively heavy element such as argon, krypton, or xenon is irradiated to the sample and the sample is machined, and next a relatively light element such as helium or neon is irradiated to the sample to observe a frontmost surface of the sample. Next, the electron beam can be irradiated to the sample and an electron transmitted through the sample can be detected to observe inside of the sample. Upon detection of the transmitting electron, there are: a case where the electron beam is scanned to provide a scanning and transmitting electron microscope image; and a case where, without scanning the electron beam, the transmitting electron is imaged and detected to provide a transmitting electron microscope image. In case of imaging, an electron focusing optical system is included.

Moreover, with the scanning charged particle radiation microscope described above, a scanning ion image is provided by scanning an ion beam by an ion beam scanning electrode. However, in this case, upon passage of the ion beam through the ion lens, the ion beam tilts and is thus distorted. Thus, there has arisen a problem that the beam diameter does not become small. Thus, instead of scanning the ion beam, the sample stage may be mechanically scanned and moved in two orthogonal directions. In this case, secondary particles discharged from the sample can be detected and subjected to luminance modulation, thereby providing a scanning ion image onto the image display means of the calculation processor. That is, high-resolution observation of the sample front surface with less than 5 nm is realized. In this case, the ion beam can always be held in the same direction with respect to the objective lens, which can therefore make the ion beam distortion relatively small.

This can be realized by use of, for example, a sample stage combining first and second stages. The first stage is a four-axis mobile stage capable of moving over several centimeters and for example, is capable of moving in two directions (X and Y directions) perpendicular to a plane, moving in a height direction (Z direction), and tilting (in T direction). The second stage is a two-axis mobile stage capable of moving over several micrometers, and for example, is capable of moving in the two directions (X and Y directions) perpendicular to the plane.

For example, the formation is achieved by arranging the second stage driven by a piezo element onto the first stage driven by an electric motor. For, for example, search of sample observation position, the sample is moved by use of the first stage, and for the high-resolution observation, slight movement is made by use of the second stage. This provides an ion microscope capable of ultrahigh-resolution observation.

The scanning ion microscope has been described above as an example of the charged particle radiation device of the invention. However, the charged particle radiation device of the invention is applicable not only to the scanning ion microscope but also to a transmitting ion microscope and an ion beam processing device.

Next, a vacuum pump 12 that evacuates the electric field dissociation ion source will be described. It is preferable to form the vacuum pump 12 with a combination of a non-evaporable getter pump and an ion pump, a combination of the non-evaporable getter pump and a noble pump, or a combination of the non-evaporable getter pump and an excel pump. Moreover, it may be a sublimation pump. That is, it is preferable to use a vacuum pump not accompanied by mechanical motion, using a gas molecule absorption phenomenon. It was found that the use of such a pump can reduce the influence of vibration of the vacuum pump 12 and enables the high-resolution observation. It was found that when a turbo molecule pump is used as the vacuum pump 12, vibration of the turbo molecule pump may interrupt sample observation by the ion beam. However, it was found that even if the turbo molecule pump is fitted to any vacuum container of the ion beam device, stopping the turbo molecule pump at time of the sample observation by the ion beam enables the high-resolution observation. That is, in the invention, the main evacuating pump for the sample observation by the ion beam is formed of the combination of the non-evaporable getter pump and the ion pump, the combination of the non-evaporable getter pump and the noble pump, or the combination of the non-evaporable getter pump and the excel pump, but configuration such that the turbo molecule pump is fitted does not disturb the object of the invention.

The non-evaporable getter pump is a vacuum pump formed by using an alloy that absorbs gas through activation as a result of heating. In a case where helium is used ionized gas of the gas electric field dissociation ion source, a relatively large amount of helium is inside the vacuum container. However, the non-evaporable getter pump exhausts little helium. That is, the getter front surface is not saturated by a gas-absorbing molecule. Thus, operation time of the non-evaporable getter pump is sufficiently long. This is an advantage provided when the helium ion microscope and the non-evaporable getter pump are combined. Moreover, provided is effect that the ion radiation current is stabilized as a result of reducing impurity gas in the vacuum container.

The non-evaporable getter pump exhausts residual gas other than helium at great exhaust speed, but by doing this only, the helium stops at the ion source. Thus, a degree of vacuum becomes insufficient, and the gas electric field dissociation ion source does not operate properly. Thus, an ion pump or a noble pump with great inert gas exhaust speed is used in combination with the non-evaporable getter pump. With only the ion pump or the noble pump, the exhaust speed is insufficient. Thus, according to the invention, combining together the non-evaporable getter pump and the ion pump or the noble pump can provide the, compact, low-cost vacuum pump 12. Note that as the vacuum pump 12, a combination of a getter pump or a titanium sublimation pump that heats and evaporates metal such as titanium and absorbs a gas molecule with a metal film to achieve evacuation may be used. That is, it is preferable to use a vacuum pump that is not accompanied by mechanical motion, using the gas molecule absorption phenomenon.

The conventional technology could not provide sufficient performance of the ion microscope due to insufficient consideration given to the mechanical vibration, but the invention provides a gas electric field dissociation ion source and an ion microscope which realize mechanical vibration reduction and are capable high-resolution observation.

Next, the sample chamber evacuating pump 13 for evacuating the sample chamber 3 will be described. As the sample chamber evacuating pump 13, for example, a getter pump, a titanium sublimation pump, a non-evaporable getter pump, an ion pump, a noble pump, or an excel pump may be used. It was found that the use of such a pump can reduce the influence of vibration of the sample chamber evacuating pump 13 and enables high-resolution observation. That is, it is preferable to use a vacuum pump not accompanied by mechanical motion, using the gas molecule absorption phenomenon.

As the sample chamber evacuating pump 13, the turbo molecule pump may be used, but it is costly to realize a vibration reducing structure of the device. Moreover, it was found that even when the turbo molecule pump is fitted in the sample chamber, stopping the turbo-molecule pump at time of the sample observation by the ion beam enables the high-resolution observation. That is, in the invention, the main evacuating pump of the sample chamber at the time of the sample observation by the ion beam is formed by a combination of a non-evaporable getter pump and an ion pump, a combination of a non-evaporable getter pump and a noble pump, or a combination of a non-evaporable getter pump and an excel pump. Note that even when a turbo molecule pump is fitted as device configuration and used for vacuum roughing from the air, the object of the invention is not disturbed.

The scanning electron microscope can relatively easily realize a resolution of 0.5 nm or below by use of the turbo molecule pump. However, the ion microscope using the gas electric field dissociation ion source has a relatively large ratio (that is, approximately 1 to 0.5) of reduction of an ion beam from an ion light source to the sample. This permits maximization of characteristics of the ion source. However, vibration of the ion emitter is reproduced on the sample while hardly subjected to reduction, thus requiring more cautious measures than measures against vibrations of a conventional scanning electron microscope.

The conventional technology considers the influence of the vibration of the sample chamber evacuating pump on the sample stage, but does not consider that the vibration of the sample chamber evacuating pump has an influence on the ion emitter. Thus, the inventor of this application found that the vibration of the sample chamber evacuating pump has a serious influence on the ion emitter. The inventor of this application assumed that a non-vibrating vacuum pump such as a getter pump, a titanium sublimation pump, a non-evaporable getter pump, an ion pump, a noble pump, or an excel pump may be used as a main pump of the sample chamber evacuating pump. This reduces the vibration of the ion emitter and enables the high-resolution observation. Note that any vacuum pump which is not accompanied by mechanical motion, uses the gas molecule absorption phenomenon is permitted, and thus a name of the vacuum pump is not limited.

Moreover, the gas compressor unit (compressor) of the freezer used in this example or the helium circulating compressor unit (compressor) may become a source of noise. The noise may also vibrate the ion microscope. Thus, according to this example, a cover is provided to the gas compressor unit (compressor) to prevent noise generated by the gas compressor unit from being transmitted to outside. In stead of the cover, a noise blocking plate may be provided. Moreover, the compressor unit (compressor) may be set in a different room. This reduces vibration attributable to sound and enables the high-resolution observation.

Moreover, the non-evaporated material may be arranged in the gas molecule ionization chamber. This highly vacuums the inside of the gas molecule ionization chamber and enables highly stable ion discharge. Moreover, hydrogen is absorbed to the non-evaporated getter material or a hydrogen absorbing alloy and is heated. Using the hydrogen discharged thereby as the ionized gas no longer requires the gas supply from the gas supply pipe 25 and can realize a compact, safe gas supply mechanism.

Moreover, the non-evaporated getter material may be arranged in the gas supply pipe 25. Impurity gas in the gas supplied through the gas supply pipe 25 is reduced by the non-evaporated getter material. Thus, the ion discharge current is stabilized.

Helium or hydrogen is used as the ionized gas supplied to the gas molecule ionization chamber 15 via the gas supply pipe 25 in the invention. However, as the ionized gas, for example, neon, oxygen, argon, krypton, or xenon may be used. In a case where, for example, the neon, the oxygen, the argon, the krypton, or the xenon is used, provided is effect that a sample machining device or a sample analyzing device is provided.

Moreover, a mass analyzer may be provided in the sample chamber 3. By the mass analyzer, mass analysis of secondary ions discharged from the sample is performed. Moreover, the mass analyzer may be any of a magnetic sector-type mass analyzer, a quadrupole mass analyzer, a flight time type mass analyzer.

Alternatively, sample element may be analyzed through ion scattering spectroscopic analysis that analyzes energy of ions scattered in the sample. Especially in a case where a fan-shaped energy analyzer or the flight time energy analyzer is used, permitting high positive voltage to be applied to the sample provides effect that the element analysis can favorably be performed.

Alternatively, an Auger electron discharged from the sample may be subjected to energy analysis. This makes it easy to perform the sample element analysis and makes it possible to perform the sample observation and the element analysis by one ion microscope.

Moreover, the conventional ion beam device does not consider disturbance of an external magnetic field, but it was found that upon focusing an ion beam to less than 0.5 nm, shielding magnetism is effective. Thus, fabricating the vacuum container of the gas electric field dissociation ion source, the ion beam irradiation system, and the sample chamber with pure iron or permalloy can achieve superhigh resolution. Moreover, a plate serving as a magnetic shield may be inserted in the vacuum container. Moreover, the inventor of this application found that a structure dimension on a semiconductor sample can accurately be measured with ion beam acceleration voltage set at 50 kV or above. This is because the spatter yield of the sample by the ion beam decreases, thus lowering a degree of damage to the sample structure and improving accuracy of the dimension measurement. In particular, using hydrogen as the ionized gas decreases the spatter yield and improves the accuracy of the dimension measurement. However, attention needs to be given to a phenomenon that the helium or the hydrogen enters into a test sample to change atom position inside of the sample. It was found that this does not have a great influence on the accuracy of the structure dimension measurement of the front surface, but has an influence on electric characteristics of the device. The conventional sample test device using an ion beam does not consider this point. The inventor of this application found that the problem is solved by testing the sample through ion beam acceleration performed in a manner such that ions enter in a depth relatively less influential on the device characteristics. Moreover, in case of a device having films superposed on each other on the sample front surface, the problem is solved by controlling ion beam irradiation voltage while the depth of ion entrance is in accordance with the film thickness. That is, the problem can be solved by providing an ion beam test device capable of irradiating an ion beam to a sample with at least two kinds of irradiation voltage.

Moreover, it was found that in view of distribution of ion beam entering into the sample, providing 100 kV or above does not cause damage on the front surface and also widely distributes the ion beam in a depth direction in the sample, thus having no influence on characteristics of the inside of the sample and also permitting favorable performance of, for example, a defect test, contamination evaluation, or an adhesive substance test on the sample front surface.

Moreover, setting the acceleration voltage at +30 kV or above, setting the sample at −20 kV, and setting energy of ion beam irradiation at 50 kV or above, that is, providing a structure that permits negative voltage application to the sample can provide great energy even when the acceleration voltage of the ion source is set at relatively low voltage. A structure of the ion source is complicated for the purpose of providing low temperature and ultrahigh vacuum but providing the relatively low voltage as the acceleration voltage provides effect that the ion source structure can be simplified. Moreover, to achieve this object, it is preferable to apply a high voltage of at least 5 kV or above.

It was found that with the ion beam device shown in this example, a sample measured and tested with an ion beam during the device manufacture can be returned to the device manufacture. Moreover, the example described above provides effect that costs for the device manufacture, semiconductor device manufacture in particular, are reduced.

The example described above provides the analyzer suitable for measuring the structure dimension on the sample by the ion beam, and a length measuring device or a test device using an ion beam.

Moreover, the invention, compared to conventional measurement using an electron beam, permits accurate measurement since an obtained image has deep focal point depth. Moreover, using hydrogen as the ionized gas in particular permits accurate measurement with a small amount of the sample front surface shaved.

The invention can provide, instead of a device which machines a sample by an ion beam to form a cross section and observes the cross section with an electron microscope, a device which forms a cross section through machining by an ion beam and observes the cross section with an ion microscope, and also provide a cross section observation method.

The invention can provide a device which can perform sample observation with an ion microscope, sample observation with an electron microscope, and element analysis on its own, and an analyzer which observes and analyzes a defect, a foreign substance, etc., and a tester.

The ion microscope realizes the ultrahigh-resolution observation. However, there is no conventional example in which when the ion beam device is conventionally used as a measurement device or a tester for a structure dimension in semiconductor sample manufacturing processes, an influence of damage to the front surface of the semiconductor sample on the manufacture is considered through comparison between the iron beam irradiation and electron beam irradiation. For example, setting the energy of the ion beam at less than 1 keV results in a small ratio in which the sample changes in quality, and results in more improved accuracy of the dimension measurement than that in a case where the energy of the ion beam is set at 20 keV. Provided in this case is effect that device costs are also reduced. On the contrary, when the acceleration voltage is 50 kV or above, the resolution for observation can be made smaller than that when the acceleration voltage is low.

Moreover, the inventor of this application found that performing energy analysis of ions Rutherford-backwardly-scattered from the sample as a result of irradiating the sample with an ion beam while the acceleration voltage of the ion beam is set at 200 kV or above and further a beam diameter thereof is decreased to 0.2 nm or below permits measurement of a three-dimensional structure including a plane and a depth of a sample element on an individual atom basis. A conventional Rutherford-backwardly-scattering device has a large ion beam diameter and has difficulty in the three-dimensional measurement in an atom order, but applying the invention can realize it. Moreover, performing energy analysis of an X-ray discharged from the sample as a result of irradiating the sample with an ion beam while the acceleration voltage of the ion beam is set at 500 kV or above and further the beam diameter is reduced to 0.2 nm or below enables two-dimensional analysis of the sample element.

This example discloses a gas electric field dissociation ion source, an ion beam device, a scanning charged particle radiation microscope, and a charged particle radiation device as follows.

(1) A scanning charged particle microscope comprising: a vacuum container; an ion emitter of a needle-like shape in the vacuum container; a gas electric field dissociation ion source including an extraction electrode provided oppositely to the emitter tip and having an opening part through which ions pass; a focusing lens focusing the ions discharged from the ion source; a mobile first aperture restricting an ion beam that has passed through the focusing lens; a first deflector scanning or aligning an ion beam that has passed through the first aperture; a second deflector deflecting the ion beam that has passed through the first aperture; a second aperture restricting the ion beam that has passed through the first aperture; an objective lens focusing onto the sample the ion beam that has passed through the first aperture; and a means adapted to measure a signal volume substantially proportional to current of the ion beam that has passed through the second aperture, wherein at position of the second aperture, voltage is applied to the focusing lens to provide an ion radiation pattern in a manner such as to satisfy condition that an area or a diameter of an ion beam discharged from periphery of one atom at a tip end of the emitter tip is at least equal to or larger than an area or a diameter of an opening part of the second aperture.

(2) The scanning charged particle microscope as described in the above (1), wherein voltage condition of the focusing lens serves at least underfocus condition for condition of ion beam focus onto the opening part of the second aperture.

(3) A scanning charged particle microscope comprising: a vacuum container; an ion emitter of a needle-like shape in the vacuum container; a gas electric field dissociation ion source including an extraction electrode provided oppositely to the emitter tip and having an opening part through which ions pass; a focusing lens focusing the ions discharged from the ion source; a mobile first aperture restricting an ion beam that has passed through the focusing lens; a first deflector scanning or aligning the ion beam that has passed through the first aperture; a second deflector deflecting the ion beam that has passed through the first aperture; a second aperture restricting the ion beam that has passed through the first aperture; an objective lens focusing onto the sample the ion beam that has passed through the first aperture; and a means adapted to measure a signal volume substantially proportional to current of the ion beam that has passed through the second aperture, wherein at time of ion radiation pattern acquisition, an area of an opening part of the first aperture is larger than an area of an opening part of the second aperture.

(4) A scanning charged particle microscope comprising: a vacuum container; an ion emitter of a needle-like shape in the vacuum container; a gas electric field dissociation ion source including an extraction electrode provided oppositely to the emitter tip and having an opening part through which ions pass; a focusing lens focusing the ions discharged from the ion source; a mobile first aperture restricting an ion beam that has passed through the focusing lens; a first deflector scanning or aligning the ion beam that has passed through the first aperture; a second deflector deflecting the ion beam that has passed through the first aperture; a second aperture restricting the ion beam that has passed through the first aperture; an objective lens focusing onto a sample the ion beam that has passed through the first aperture; and a means adapted to measure a signal volume substantially proportional to current of the ion beam that has passed through the second aperture, wherein an area of an opening part of the first aperture at time of ion radiation pattern acquisition is made larger than an area of the opening part of the first aperture when the ion beam on the sample is thinned to 10 nm or below at maximum.

(5) A scanning charged particle microscope comprising: a vacuum container; an ion emitter of a needle-like shape in the vacuum container; a gas electric field dissociation ion source including an extraction electrode provided oppositely to the emitter tip and having an opening part through which ions pass; a focusing lens focusing the ions discharged from the ion source; a mobile first aperture restricting an ion beam that has passed through the focusing lens; a first deflector scanning or aligning the ion beam that has passed through the first aperture; a second deflector deflecting the ion beam that has passed through the first aperture; a second aperture restricting the ion beam that has passed through the first aperture; an objective lens focusing onto a sample the ion beam that has passed through the first aperture; and a means adapted to measure a signal volume substantially proportional to current of the ion beam that has passed through the second aperture, wherein an area of ion beam scanning by the first deflector at position of the second aperture is at least four times an area of an opening part of the second aperture.

(6) A scanning charged particle microscope comprising: a vacuum container; an ion emitter of a needle-like shape in the vacuum container; a gas electric field dissociation ion source including an extraction electrode provided oppositely to the emitter tip and having an opening part through which ions pass; a focusing lens focusing the ions discharged from the ion source; a mobile first aperture restricting an ion beam that has passed through the focusing lens; a first deflector scanning or aligning the ion beam that has passed through the first aperture; a second deflector deflecting the ion beam that has passed through the first aperture; a second aperture restricting the ion beam that has passed through the first aperture; an objective lens focusing onto a sample the ion beam that has passed through the first aperture; and a means adapted to measure a signal volume substantially proportional to current of the ion beam that has passed through the second aperture, wherein a space from a lower end of the focusing lens to the first aperture is shorter than length of the first deflector.

(7) A scanning charged particle microscope comprising: a vacuum container; an ion emitter of a needle-like shape in the vacuum container; a gas electric field dissociation ion source including an extraction electrode provided oppositely to the emitter tip and having an opening part through which ions pass; a focusing lens focusing the ions discharged from the ion source; a mobile aperture restricting an ion beam that has passed through the focusing lens; a deflector deflecting the ion beam that has passed through the first aperture; an objective lens focusing onto a sample the ion beam that has passed through the deflector; and a charged particle detector detecting secondary particles discharged from the sample as a result of irradiation of the ion beam,

wherein an ion emitter tilting means capable of mechanically changing a tilt angle of the ion emitter with respect to an ion beam irradiation axis is provided and intensities of the secondary particles discharged from the sample based on a difference in the ion emitter angle can be recorded to observe a pattern of ion radiation from the ion emitter, and

voltage is applied to the focusing lens in a manner such as to satisfy condition that at position of the mobile aperture, an area or a diameter of an ion beam discharged from periphery of one atom at a tip end of the emitter tip is at least equal to or larger than an area or a diameter of an opening part of the mobile aperture.

(8) The scanning charged particle microscope as described in the above (7),

wherein voltage condition of the focusing lens is at least underfocus condition for condition of ion beam focusing onto the opening part of the mobile aperture.

(9) A scanning charged particle microscope comprising: a vacuum container; an ion emitter of a needle-like shape in the vacuum container; a gas electric field dissociation ion source including an extraction electrode provided oppositely to the emitter tip and having an opening part through which ions pass; a focusing lens focusing the ions discharged from the ion source; a mobile aperture restricting an ion beam that has passed through the focusing lens; a deflector deflecting the ion beam that has passed through the aperture; an objective lens focusing onto a sample the ion beam that has passed through the deflector; and a charged particle, detector detecting secondary particles discharged from the sample as a result of irradiation of the ion beam,

wherein an ion emitter tilting means capable of mechanically changing a tilt angle of the ion emitter with respect to an ion beam irradiation axis is provided and intensities of the secondary particles discharged from the sample based on a difference in an ion emitter angle can be recorded to observe a pattern of ion radiation from the ion emitter, and

a space from a lower end of the focusing lens to the mobile aperture is shorter than length of the deflector.

(10) A scanning charged particle microscope comprising: a vacuum container; an ion emitter of a needle-like shape in the vacuum container; a gas electric field dissociation ion source including an extraction electrode provided oppositely to the emitter tip and having an opening part through which ions pass; a focusing lens focusing the ions discharged from the ion source; a mobile aperture restricting an ion beam that has passed through the focusing lens; a deflector deflecting the ion beam that has passed through the aperture; an objective lens focusing onto a sample the ion beam that has passed through the deflector; and a charged particle detector detecting secondary particles discharged from the sample as a result of irradiation of the ion beam,

wherein a fixed aperture is arranged between the deflector and the objective lens, an ion emitter tilting means capable of mechanically changing a tilt angle of the ion emitter with respect to an ion beam irradiation axis is provided, and intensities of the secondary particles discharged from the sample based on a difference in an ion emitter angle can be recorded to observe a pattern of ion radiation from the ion emitter

(11) The scanning charged particle microscope as described in the above (1) to (10),

wherein a tip end of the ion emitter of the needle-like shape is a nanotip formed of an atom pyramid, and the number of atoms at the tip end is 4 to 15.

(12) The scanning charged particle microscope as described in the above (1) to (11),

wherein a cooling mechanism of cooling the ion emitter includes: a coolness generating means adapted to generate coolness by expanding high-pressure gas generated by a compressor unit; and a freezer cooling a stage with the coolness of the coolness generating means.

(13) The scanning charged particle microscope as described in the above (1) to (11),

wherein the cooling mechanism of cooling the ion emitter includes: a coolness generating means adapted to generate coolness by expanding first high-pressure gas generated by a compressor unit; and a cooling means adapted to cool a cooled body with gas cooled by the coolness of the coolness generating means.

(14) The scanning charged particle microscope as described in the above (1) to (11),

wherein the cooling mechanism of cooling the ion emitter includes: a coolness generating means adapted to generate coolness by expanding first high-pressure gas generated by a compressor unit; and a cooling means adapted to cool a cooled body with second high-pressure gas cooled by the coolness of the coolness generating means.

(15) The scanning charged particle microscope as described in the above (12) to (13),

wherein a vibration absorption mechanism between the freezer and the vacuum container includes at least a mechanism of obstructing vibration transmission with helium or neon gas.

(16) A gas electric field dissociation ion source comprising: a vacuum container; an ion emitter of a needle-like shape in the vacuum container; and an extraction electrode provided oppositely to the emitter tip and having an opening part through which ions pass,

wherein a mechanism of varying conductance with which a gas molecule ionization chamber is evacuated is a valve operable outside of the vacuum container and can be mechanically separated from a wall structure of the ionization chamber.

(17) A charged particle radiation device comprising: a vacuum container; an ion emitter of a needle-like shape in the vacuum container; a gas electric field dissociation ion source including an extraction electrode provided oppositely to the emitter tip and having an opening part through which ions pass and a gas molecule ionization chamber roughly surrounding the ion emitter, and extracting an electron beam by applying high negative voltage to the ion emitter; and an electron source,

wherein the gas molecule ionization chamber has an openable and closable opening part varying evacuation conductance, and upon the electron beam extraction, the openable and closable opening part varying the evacuation conductance is in an open state.

(18) The charged particle radiation device as described in the above (17), including a compound lens combining a magnetic-sector type lens and an electrostatic lens with an objective lens for focusing the electron beam.

(19) A sample observation method of: by using the charged particle radiation device as described in the above (17), irradiating a sample with a relatively heavy element such as argon, krypton, or xenon; machining the sample; irradiating the sample with a relatively light element such as helium or neon to observe a frontmost surface of the sample; irradiating the sample with an electron beam; and detecting an electron that has passed through the sample to observe inside of a sample. Further, the charged particle radiation device as described in the above (17), including an imaging optical system imaging and detecting the electron that has passed through the sample.

(20) An ion beam device comprising: a vacuum container; an evacuation mechanism; an emitter tip as a needle-like anode; an extraction electrode as a cathode; and a cooling mechanism for the emitter tip, etc., and including: a gas electric field dissociation ion source supplying a gas molecule to vicinity of a tip end of the emitter tip and ionizing the gas molecule at a tip end part of the emitter tip with an electric field; a lens and an objective lens focusing an ion beam extracted from the emitter tip; a sample chamber having a sample built in; and a secondary particle detector detecting secondary particles discharged from the sample,

wherein element analysis can be done by applying high negative voltage to the emitter tip, extracting an electron from the emitter tip and irradiating it to the sample, and detecting an X-ray or an Auger electron discharged from the sample, and a scanning ion image and an element-analyzed image with a resolution of 1 nm or below can be arrayed or superposed on each other for display.

(21) A device manufacturing method in device manufacture including testing by use of: a vacuum container; an evacuation mechanism; an emitter tip as a needle-like anode in the vacuum container; an extraction electrode as a cathode; and a cooling mechanism for the emitter tip, etc., a gas electric field dissociation ion source supplying a gas molecule to vicinity of a tip end of the emitter tip and ionizing the gas molecule at a tip end part of the emitter tip with an electric field; a lens and an objective lens focusing an ion beam extracted from the emitter tip; a sample chamber having a sample built in; and an ion beam tester detecting secondary particles discharged from the sample and measuring a structure dimension of a sample front surface,

wherein with acceleration voltage of the ion beam set at 50 kV or above, top of the device sample is tested, and the tested sample is returned to the device manufacture.

(22) An ion beam tester including: a vacuum container; an evacuation mechanism; an emitter tip as a needle-like anode in the vacuum container; an extraction electrode as a cathode; and a cooling mechanism for the emitter tip, etc., the ion beam tester further including: a gas electric field dissociation ion source supplying a gas molecule to vicinity of a tip end of the emitter tip and ionizing the gas molecule at a tip end part of the emitter tip with an electric field; a lens and an objective lens focusing an ion beam extracted from the emitter tip; and a sample chamber having a sample built in, and detecting secondary particles discharged from the sample and measuring a structure dimension of a sample front surface. wherein the ion beam can be irradiated to the sample at least two kinds of irradiation voltage.

(23) An ion beam tester including: a vacuum container; an evacuation mechanism; an emitter tip as a needle-like anode in the vacuum container; an extraction electrode as a cathode; and a cooling mechanism for the emitter tip, etc., the ion beam tester further including: a gas electric field dissociation ion source supplying a gas molecule to vicinity of a tip end of the emitter tip and ionizing the gas molecule at a tip end part of the emitter tip with an electric field; a lens and an objective lens focusing an ion beam extracted from the emitter tip; and a sample chamber having a sample built in, and detecting secondary particles discharged from the sample and measuring a structure dimension of a sample front surface,

wherein energy of the ion beam is 100 keV or above.

(24) The charged particle radiation device as described in the above (21) to (23),

wherein negative voltage can be applied to the sample.

(25) A sample element analysis method using an ion beam device comprising: a vacuum container; an evacuation mechanism; an emitter tip as a needle-like anode in the vacuum container; an extraction electrode as a cathode; and a cooling mechanism for the emitter tip, etc., the ion beam device further comprising: a gas electric field dissociation ion source supplying a gas molecule to vicinity of a tip end of the emitter tip and ionizing the gas molecule at a tip end part of the emitter tip with an electric field; a lens and an objective lens focusing an ion beam extracted from the emitter tip; a sample chamber having a sample built in; and a secondary particle detector detecting secondary particles discharged from the sample,

wherein with acceleration voltage of the ion beam set at 200 kV or above and a beam diameter decreased to 0.2 nm or below, the ion beam is irradiated to the sample and ions Ruther-backwardly-scattered from the sample are subjected to energy analysis, and a three-dimensional structure including a plane and a depth of a sample element is measured on an individual atom basis.

(26) A sample element analysis method using an ion beam device comprising: a vacuum container; an evacuation mechanism; an emitter tip as a needle-like anode in the vacuum container; an extraction electrode as a cathode; and a cooling mechanism for the emitter tip, etc., the ion beam device further comprising: a gas electric field dissociation ion source supplying a gas molecule to vicinity of a tip end of the emitter tip and ionizing the gas molecule at a tip end part of the emitter tip with an electric field; a lens and an objective lens focusing an ion beam extracted from the emitter tip; a sample chamber having a sample built in; and a secondary particle detector detecting secondary particles discharged from the sample, wherein with 500 kV or above provided and a beam diameter decreased to 0.2 nm or below, the ion beam is irradiated to the sample, and an X-ray discharged from the sample is subjected to energy analysis to perform two-dimensional element analysis.

(27) A ion beam device comprising: a vacuum container; an evacuation mechanism; an emitter tip as a needle-like anode in the vacuum container; an extraction electrode as a cathode; and a cooling mechanism for the emitter tip, etc., the ion beam device further comprising: a gas electric field dissociation ion source supplying a gas molecule to vicinity of a tip end of the emitter tip and ionizing the gas molecule at a tip end part of the emitter tip with an electric field; a lens and an objective lens focusing an ion beam extracted from the emitter tip; a sample chamber having a sample built in; and a secondary particle detector detecting secondary particles discharged from the sample, wherein the emitter tip is cooled to 50 K or below, a magnification ratio in which an ion discharged from the emitter tip is projected onto the sample set at less than 0.2, and further vibration of relative position between the emitter tip and the sample is set at 0.1 nm or below, whereby resolution of a scanning ion image is set at 0.2 nm or below.

(28) An ion beam device comprising:

a gas electric field dissociation ion source for generating an ion beam;
an ion irradiation light system for guiding onto a sample the ion beam from the gas electric field dissociation ion source;
a vacuum container storing the gas electric field dissociation ion source and the ion irradiation light system;
a sample chamber storing a sample stage holding the sample; and
a cooling mechanism for cooling the gas electric field dissociation ion source,
wherein the cooling mechanism is a cooling mechanism cooling a cooled body by: a coolness generating means adapted to generate coolness by expanding first high-pressure gas generated by a compressor unit; and helium gas as a second moving refrigerant cooled by the coldness of the coolness generating means and circulated by the compressor unit.

(29) An ion beam device comprising:

a gas electric field dissociation ion source for generating an ion beam;
an ion irradiation light system for guiding onto a sample an ion beam from the gas electric field dissociation ion source;
a vacuum container storing the gas electric field dissociation ion source and the ion irradiation light system;
a sample chamber storing a sample stage holding the sample;
a cooling mechanism for cooling the gas electric field dissociation ion source; and
a base plate supporting the gas electric field dissociation ion source, the vacuum container, and the sample chamber, wherein a main material of the vacuum container of any of the gas electric field dissociation ion source, the ion beam irradiation system, and the sample chamber is iron or parmalloy, and resolution of a scanning ion image is 0.5 nm or below.

### REFERENCE SIGNS LIST

1 . . . Gas electric field dissociation ion source, 2 . . . Ion beam irradiation system column, 3 . . . Sample chamber, 4 . . . Cooling mechanism, 5 . . . . Focusing lens, 6 . . . Mobile aperture, 7 . . . Deflector, 8 . . . Objective lens, 9 . . . Sample, 10 . . . Sample stage, 11 . . . Secondary particle detector, 12 . . . Ion source evacuating pump, 13 . . . Sample chamber evacuating pump, 14 . . . Ion beam, 14A . . . Light axis, 15 . . . Gas molecule ionization chamber, 16 . . . Compressor, 17 . . . Device mount, 18 . . . Base plate, 19 . . . Vibration absorption mechanism, 20 . . . Floor, 21 . . . Emitter tip, 22 . . . Filament, 23 . . . Filament mount, 24 . . . Extraction electrode, 25 . . . Gas supply pipe, 26 . . . . Support bar, 27 . . . Opening part, 28 . . . . Side wall, 29 . . . Top panel, 30 . . . Resistive heater, 34 . . . Cover member, 35 . . . . First deflector, 36 . . . Second aperture, 40 . . . Freezer, 40A . . . Central axis line, 41 . . . Main body, 42A, 42B . . . Stage, 43 . . . . Pot, 46 . . . Helium gas, 53 . . . Cooling conducting bar, 54 . . . Copper graticule, 57 . . . Cooling conducting tube, 61 . . . Tilt mechanism, 62 . . . Insulation material, 63 . . . Insulation material, 64 . . . Emitter base mount, 65 . . . Central axis line, 66 . . . Vertical line, 68 . . . Vacuum container, 70 . . . Planar movement mechanism, 72 . . . Reflecting mirror, 73 . . . View port, 74 . . . Optical camera, 75 . . . Light detection device, 76 . . . Light detection means, 91 . . . Electric field dissociation ion source controller, 92 . . . . Freezer controller, 93 . . . Lens controller, 94 . . . . First aperture controller, 95 . . . Ion beam scanning controller, 96 . . . Secondary electron detector controller, 97 . . . Sample stage controller, 98 . . . Evacuating pump controller, 99 . . . Calculation processor, 161, 162 . . . Bellows, 195 . . . First deflector controller, 196 . . . Tilt mechanism controller

1. A charged particle microscope comprising:
a vacuum container;
an emitter tip arranged in the vacuum container;
an extraction electrode having an opening part through which ions generated by the emitter tip pass;
an ion source having the emitter tip and the extraction electrode;
a focusing lens focusing an ion beam discharged from the ion source; and
a first deflector deflecting the ion beam that has passed through the focusing lens,
wherein a first aperture restricting the ion beam that has passed through the focusing lens is provided between the focusing lens and the first deflector.

2. The charged particle microscope according to claim 1,
wherein the first aperture is mobile within a plane substantially perpendicular to the ion beam.

3. The charged particle microscope according to claim 1, further comprising:
a second deflector deflecting the ion beam that has passed through the first aperture;
a second aperture restricting the ion beam that has passed through the first aperture;
an objective lens focusing onto a sample the ion beam that has passed through the first aperture; and
a signal volume measurement means adapted to measure a signal volume substantially proportional to ion beam current of the ion beam that has passed through the second aperture.

4. The charged particle microscope according to claim 3,
wherein the second aperture restricts the ion beam that has passed through the objective lens.

5. The charged particle microscope according to claim 3,
wherein the signal volume measurement means is a charged particle detector detecting secondary particles discharged from the sample as a result of irradiation of the ion beam.

6. The charged particle microscope according to claim 5,
wherein a sample for adjustment is loaded.

7. The charged particle microscope according to claim 3,
wherein the signal volume measurement means includes at least one of: an ammeter measuring the ion beam current; an ammeter connected to the sample; a means adapted to amplify the ion beam current with a channel thoron for measurement; and a means adapted to achieve amplification with a multi-channel plate for measurement.

8. The charged particle microscope according to claim 3,
wherein the second aperture also serves as an electrode forming the objective lens.

9. The charged particle microscope according to claim 1,
wherein a tip end of the emitter tip is a nano-pyramid.

10. The charged particle microscope according to claim 9, further comprising
a display means adapted to display an ion radiation pattern of the nano-pyramid.

11. A charged particle microscope comprising:
a vacuum container;
an emitter tip arranged in the vacuum container;
an extraction electrode having an opening part through which ions generated by the emitter tip pass;
an ion source having the emitter tip and the extraction electrode; and
a focusing lens focusing an ion beam discharged from the ion source, the charged particle microscope further comprising:
a tilt angle adjustment means adapted to be capable of adjusting a tilt angle with respect to an irradiation axis of the ion beam; and
a display means adapted to display an ion radiation pattern depending on a difference in the tilt angle.

12. The charged particle microscope according to claim 11,
wherein a driving mechanism forming the tilt angle adjustment means is arranged in the ion source, and tilting can be done while position of a tip end of an ion emitter having the emitter tip is kept substantially constant.

13. The charged particle microscope according to claim 11,
wherein the driving mechanism driving the tilt angle adjustment means uses a piezo element.

14. A charged particle microscope comprising:
a vacuum container;
an emitter tip arranged in the vacuum container;
an extraction electrode having an opening part through which ions generated by the emitter pass;
an ion source having the emitter and the extraction electrode;
a focusing lens focusing an ion beam discharged from the ion source; and
a first deflector deflecting the ion beam that has passed through the focusing lens, the charged particle microscope further comprising
a light detection means adapted to detect from the opening part light generated from the emitter tip or a filament connected to the emitter tip.

15. The charged particle microscope according to claim 14, further comprising
a change means adapted to change relative position between the emitter and the extraction electrode.

16. The charged particle microscope according to claim 14, further comprising
a control means adapted to control, based on a signal detected by the light detection means, at least one of voltage applied to the filament, current, resistance, and temperature.

17. The charged particle microscope according to claim 14, further comprising
a means adapted to permit the light detection means to observe the emitter or the filament connected to the emitter outside of the vacuum container through the opening part.

18. The charged particle microscope according to claim 14,
wherein a sample stage loaded with the sample has a mobile function within a plane substantially perpendicular to the ion beam, and
the sample stage is provided with a means adapted to permit observation of the emitter or the filament connected to the emitter outside of the vacuum container through the opening part.

19. The charged particle microscope according to claim 14,
wherein a means adapted to permit the observation of the emitter or the filament connected to the emitter outside of the vacuum container through the opening part is provided between the focusing lens and the objective lens.

20. The charged particle microscope according to claim 14,
wherein a first aperture is provided between the focusing lens and the first deflector, and
at least part of the light detection means is included in the first aperture.
